(19) United States
(12) Patent Application Publication
(10) Pub. No.: US 2025/0359438 A1
(43) Pub. Date: Nov. 20, 2025

(54) DISPLAY DEVICE, METHOD FOR MANUFACTURING THE DISPLAY DEVICE, AND HEAD MOUNTED DISPLAY INCLUDING THE DISPLAY DEVICE

(71) Applicant: Samsung Display Co., LTD., Yongin-si (KR)

(72) Inventor: Chun Gi YOU, Yongin-si (KR)

(21) Appl. No.: 19/058,701

(22) Filed: Feb. 20, 2025

(30) Foreign Application Priority Data
May 20, 2024 (KR) 10-2024-0065296

(51) Int. Cl. H10K 59/122; G02B 27/01; H10K 59/12; H10K 59/131; H10K 59/80

(52) U.S. Cl. CPC H10K 59/122; G02B 27/0172; H10K 59/1201; H10K 59/131; H10K 59/80517; G02B 2027/0178

(57) ABSTRACT

A display device, a method for manufacturing the display device, and a head mounted display are provided. The display device includes a substrate, an insulating film on the substrate, a connection electrode on the insulating film, a reflective electrode on the connection electrode, a first electrode on the reflective electrode, a first pixel defining film on a first portion of the first electrode and exposing a second portion of the first electrode, at least one light-emitting layer on a second area of a top surface of the first electrode, and a second electrode on the at least one light-emitting layer. A thickness of the second portion of the first electrode is less than a thickness of the first portion of the first electrode.

### CROSS-REFERENCE TO RELATED APPLICATION

The present application claims priority to and the benefit of Korean Patent Application No. 10-2024-0065296, filed on May 20, 2024, in the Korean Intellectual Property Office, the entire disclosure of which is incorporated by reference herein.

### BACKGROUND

### 1. Field

One or more embodiments of the present disclosure relate to a display device, a method for manufacturing the display device, and a head mounted display including the display device.

### 2. Description of the Related Art

A head mounted display (HMD) is an image display device that is worn on a user's head in the form of glasses or helmets to form a focus at a close distance in front of the user's eyes. The head mounted display may implement virtual reality (VR) or augmented reality (AR).

The head mounted display magnifies an image displayed on a small display device by using a plurality of lenses, and displays the magnified image. Therefore, the display device applied to the head mounted display needs to provide high-resolution images, for example, images with a resolution of 3000 PPI (Pixels Per Inch) or higher. To this end, an organic light-emitting diode on silicon (OLEDoS), which is a high-resolution small organic light-emitting display device, is used as the display device applied to the head mounted display. The OLEDOS is an image display device in which an organic light-emitting diode (OLED) is disposed on a semiconductor wafer substrate including complementary metal oxide semiconductor (CMOS).

### SUMMARY

Aspects and features of embodiments of the present disclosure provide a display device capable of providing a high-resolution image.

Aspects and features of embodiments of the present disclosure also provide a method for manufacturing a display device capable of providing a high-resolution image.

Aspects and features of embodiments of the present disclosure also provide a head mounted display capable of providing high-resolution images.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the present disclosure, there is provided a display device including a substrate, an insulating film on the substrate, a connection electrode on the insulating film, a reflective electrode on the connection electrode, a first electrode on the reflective electrode, a first pixel defining film on a first portion of the first electrode and exposing a second portion of the first electrode, at least one light-emitting layer on a second area of a top surface of the first electrode, and a second electrode on the at least one light-emitting layer. A thickness of the second portion of the first electrode is less than a thickness of the first portion of the first electrode.

The first pixel defining film may be on a side surface of the first electrode, a side surface of the reflective electrode, and a side surface of the connection electrode.

The insulating film may include a first area overlapping the connection electrode in a thickness direction of the substrate, and a second area around the first area. The first pixel defining film may be on the second area of the insulating film.

The display device may further include a planarization film on the first pixel defining film on the second area of the insulating film. The first pixel defining film may include an inorganic material different from the planarization film.

The display device may further include a second pixel defining film on the planarization film and the first pixel defining film.

The display device may further include a trench penetrating the first pixel defining film, the planarization film, and the second pixel defining film.

The display device may further include a first pad conductive layer on the insulating film and including a same material as the connection electrode, a second pad conductive layer on the first pad conductive layer and including a same material as the reflective electrode, and a third pad conductive layer on the second pad conductive layer and including a same material as the first electrode.

The first pixel defining film may be on a first portion of the third pad conductive layer, and exposes a second portion of the third pad conductive layer.

A thickness of the second portion of the first electrode may be less than a thickness of the third pad conductive layer.

A thickness of the first portion of the first electrode may be a same as a thickness of the third pad conductive layer.

According to one or more embodiments of the present disclosure, there is provided a display device including a substrate, an insulating film on the substrate, a connection electrode on the insulating film, a reflective electrode on the connection electrode, a first electrode on the reflective electrode, a first pad conductive layer on the insulating film and including a same material as the connection electrode, a second pad conductive layer on the first pad conductive layer and including a same material as the reflective electrode, a third pad conductive layer on the second pad conductive layer and including a same material as the first electrode, a first pixel defining film on a first portion of the first electrode and exposing a second portion of the first electrode, at least one light-emitting layer on a second area of a top surface of the first electrode, and a second electrode on the at least one light-emitting layer. A thickness of the second portion of the first electrode is less than a thickness of the third pad conductive layer.

A thickness of the second portion of the first electrode may be less than a thickness of the first portion of the first electrode.

A thickness of the first portion of the first electrode may be a same as a thickness of the third pad conductive layer.

The first pixel defining film may be on a first portion of the third pad conductive layer, and exposes a second portion of the third pad conductive layer.

According to one or more embodiments of the present disclosure, there is provided a method for manufacturing a display device including forming an insulating film on a substrate, forming a connection electrode layer on the insulating film, forming a reflective electrode layer on the connection electrode layer, and forming a first electrode layer on the reflective electrode layer, etching the connection electrode layer, the reflective electrode layer, and the first electrode layer using a single mask to form a plurality of connection electrodes, a plurality of reflective electrodes, and a plurality of first electrodes, forming a pixel defining film on a first portion of each of the plurality of first electrodes and exposing a second portion thereof, and etching the second portion of each of the plurality of first electrodes such that a thickness of the second portion of each of the plurality of first electrodes is less than a thickness of the first portion of each of the plurality of first electrodes.

The etching of the connection electrode layer, the reflective electrode layer, and the first electrode layer using the single mask to form the plurality of connection electrodes, the plurality of reflective electrodes, and the plurality of first electrodes may include etching the connection electrode layer, the reflective electrode layer, and the first electrode layer using the single mask to form a pad conductive layer concurrently with the plurality of connection electrodes, the plurality of reflective electrodes, and the plurality of first electrodes.

The pad conductive layer may include a first pad conductive layer including a same material as the plurality of connection electrodes, a second pad conductive layer including a same material as the plurality of reflective electrodes, and a third pad conductive layer including a same material as the plurality of first electrodes.

The forming of the pixel defining film on the first portion of each of the plurality of first electrodes and exposing the second portion thereof may include forming the pixel defining film on a first portion of the third pad conductive layer and exposing a second portion thereof.

The method may further include before etching the second portion of each of the plurality of first electrodes such that the thickness of the second portion of each of the plurality of first electrodes is less than the thickness of the first portion of each of the plurality of first electrodes, forming a mask pattern covering the second portion of the third pad conductive layer.

According to one or more embodiments of the present disclosure, there is provided a head mounted display including at least one display device, a housing configured to accommodate the at least one display device, and an optical member configured to magnify a display image of the at least one display device or change an optical path. The at least one display device includes a substrate, an insulating film on the substrate, a connection electrode on the insulating film, a reflective electrode on the connection electrode, a first electrode on the reflective electrode, a first pixel defining film on a first portion of the first electrode and exposing a second portion of the first electrode, at least one light-emitting layer on a second area of a top surface of the first electrode, and a second electrode on the at least one light-emitting layer. A thickness of the second portion of the first electrode is less than a thickness of the first portion of the first electrode.

In one or more embodiments, an electronic device including a display device; and a processor configured to provide input image data to the display device, the display device including: a substrate; an insulating film on the substrate; a connection electrode on the insulating film; a reflective electrode on the connection electrode; a first electrode on the reflective electrode; a first pixel defining film on a first portion of the first electrode and exposing a second portion of the first electrode; at least one light-emitting layer on a second area of a top surface of the first electrode; a second electrode on the at least one light-emitting layer; and a first pad conductive layer on the insulating film and comprising a same material as the connection electrode, wherein a thickness of the second portion of the first electrode is less than a thickness of the first portion of the first electrode.

The electronic device includes a mobile phone, a smartphone, a tablet personal computer, a mobile communication terminal, an electronic organizer, an electronic book, a portable multimedia player (PMP), a navigation system, an ultra mobile PC (UMPC), a television, a laptop, a monitor, a billboard, or an Internet-of-Things (IoT) terminal.

According to the aforementioned and other embodiments of the present disclosure, and according to the head mounted display including the display device according to embodiments, a connection electrode, a reflective electrode, and a first electrode may be patterned at once using a single mask, so that the number of mask processes may be reduced compared to the case in which each of the plurality of first electrodes is connected to the exposed reflective electrode through a contact hole penetrating an insulating film, thereby reducing manufacturing cost and increasing manufacturing efficiency.

According to the aforementioned and other embodiments of the present disclosure, and according to the head mounted display including the display device according to embodiments, the thickness of a second portion of the first electrode exposed without being covered by a pixel defining film is less than the thickness of a first portion of the first electrode covered by the pixel defining film, so that the light transmittance of the second portion of the first electrode may be higher than the light transmittance of the first portion of the first electrode. Therefore, the proportion of light emitted due to optical micro-cavity between the reflective electrode and the second electrode may be increased. Accordingly, the light emission efficiency of a first emission area, the light emission efficiency of a second emission area, and the light emission efficiency of a third emission area may be improved.

According to the aforementioned and other embodiments of the present disclosure, and according to the head mounted display including the display device according to embodiments, a separate step layer for setting a first resonance distance between a first organic light-emitting layer of a first stack layer and the reflective electrode, a second resonance distance between a second organic light-emitting layer of a second stack layer and the reflective electrode, and a third resonance distance between a third organic light-emitting layer of a third stack layer and the reflective electrode may be omitted, so that the number of masks for forming step layers through a photolithography process may be reduced thereby reducing manufacturing cost.

### BRIEF DESCRIPTION OF THE DRAWINGS

The above and other embodiments of the present disclosure will become more apparent by describing embodiments thereof with reference to the attached drawings, in which:

FIG. 1 is an exploded perspective view showing a display device according to one or more embodiments;

FIG. 2 is a block diagram illustrating a display device according to one or more embodiments;

FIG. 3 is an equivalent circuit diagram of a first sub-pixel according to one or more embodiments;

FIG. 4 is a layout diagram illustrating an example of a display panel according to one or more embodiments;

FIG. 5 is a layout diagram showing an example of the display area of FIG. 4;

FIG. 6 is a layout diagram showing another example of the display area of FIG. 4;

FIG. 7 is a cross-sectional view illustrating an example of a display panel taken along the line 11-11′ of FIG. 5;

FIG. 8 is a cross-sectional view specifically showing an area A1 of FIG. 7;

FIG. 9 is a cross-sectional view specifically illustrating an example of an area A2 of FIG. 8;

FIG. 10 is a layout diagram illustrating an example of the first pad of the first pad portion of FIG. 4;

FIG. 11 is a cross-sectional view illustrating an example of a display panel taken along the line 12-12′ of FIG. 10;

FIG. 12 is a plan view specifically illustrating an example of an area A3 of FIG. 11

FIG. 13 is a layout diagram illustrating still another example of the display area of FIG. 4;

FIG. 14 is a layout diagram illustrating still another example of the display area of FIG. 4;

FIG. 15 is a cross-sectional view illustrating an example of the display panel taken along the line 13-13′ of FIG. 13;

FIG. 16 is a cross-sectional view specifically illustrating an example of an area A4 of FIG. 15;

FIG. 17 is a flowchart illustrating a method for manufacturing a display panel according to one or more embodiments;

FIGS. 18-26 are cross-sectional views specifically showing the area A1 to describe a method for manufacturing a display panel according to one or more embodiments;

FIG. 27 is a cross-sectional view specifically showing the area A2 to describe a method for manufacturing a display panel according to one or more embodiments;

FIG. 28 is a cross-sectional view specifically showing the area A3 to describe a method for manufacturing a display panel according to one or more embodiments;

FIG. 29 is a perspective view illustrating a head mounted display according to one or more embodiments;

FIG. 30 is an exploded perspective view illustrating an example of the head mounted display of FIG. 29; and

FIG. 31 is a perspective view illustrating a head mounted display according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions, such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression, such as “at least one of A and/or B” may include A, B, or A and B. As used herein, the term “and/or” includes any and all combinations of one or more of the associated listed items. For example, the expression, such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

The electronic or electric devices and/or any other relevant devices or

components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

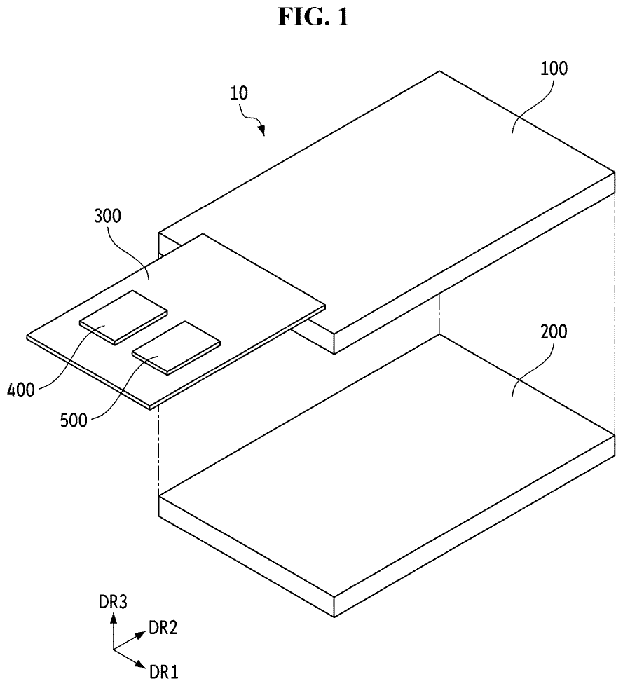

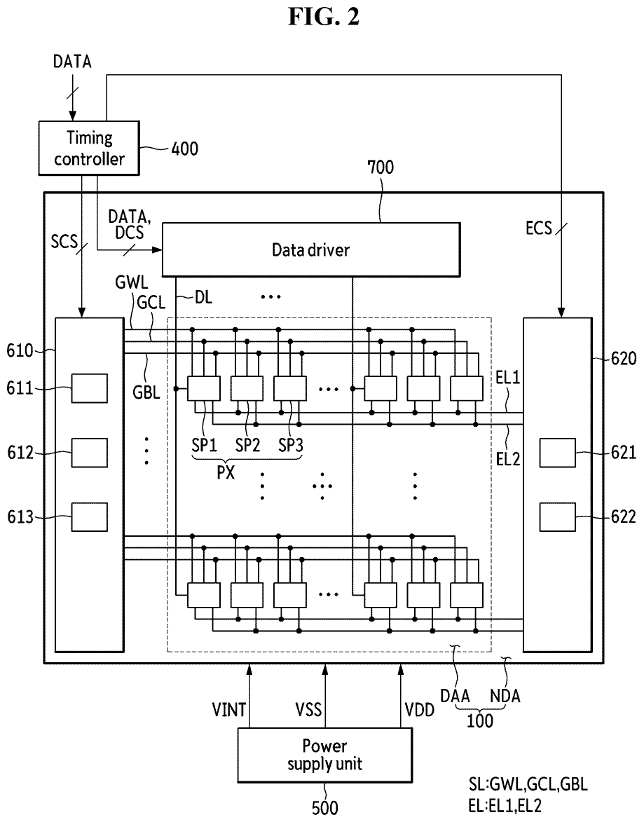

FIG. 1 is an exploded perspective view showing a display device according to one or more embodiments. FIG. 2 is a block diagram illustrating a display device according to one or more embodiments.

Referring to FIGS. 1 and 2, a display device 10 according to one or more embodiments is a device displaying a moving image and/or a still image. The display device 10 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC), and/or the like. For example, the display device 10 according to one or more embodiments may be applied as a display unit of a television, a laptop, a monitor, a billboard, and/or an Internet-of-Things (IoT) terminal. Alternatively, the display device 10 according to one or more embodiments may be applied to a smart watch, a watch phone, a head mounted display (HMD) for implementing virtual reality and augmented reality, and/or the like.

The display device 10 according to one or more embodiments includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a suitable curvature (e.g., a predetermined curvature). The planar shape of the display panel 100 is not limited to a quadrilateral shape, and may be a shape similar to another polygonal shape, a circular shape, and/or an elliptical shape. The planar shape of the display device 10 may conform to the planar shape of the display panel 100, but the present disclosure is not limited thereto.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as shown in FIG. 2.

The plurality of pixels PX may be disposed in the display area DAA. The plurality of pixels PX may be arranged in a matrix form along the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1, while being arranged along the second direction DR2. The plurality of data lines DL may extend in the second direction DR2, while being arranged along the first direction DR1.

The plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

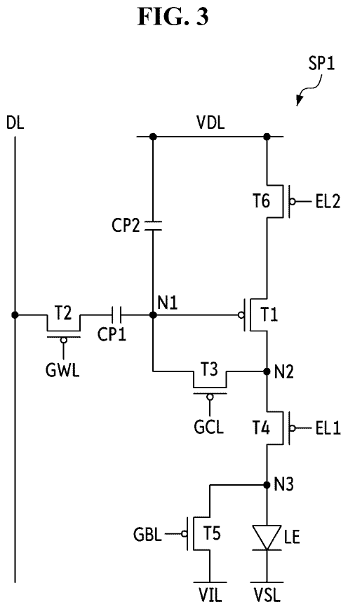

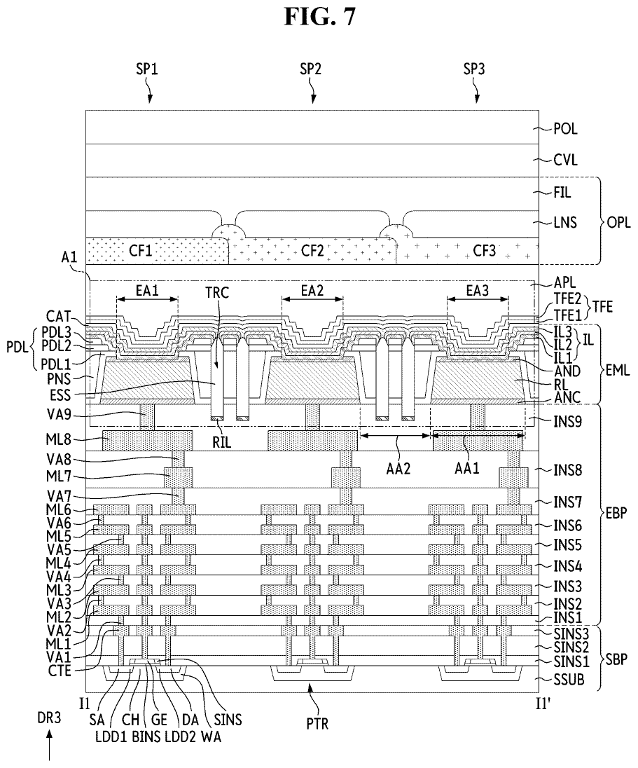

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and disposed on a semiconductor substrate SSUB (see FIG. 7). For example, the plurality of pixel transistors of the data driver 700 may be formed of complementary metal oxide semiconductor (CMOS), but the present disclosure is not limited thereto.

Each of the plurality of sub-pixels SP1, SP2, and SP3 may be connected to one write scan line GWL from among the plurality of write scan lines GWL, one control scan line GCL from among the plurality of control scan lines GCL, one bias scan line GBL from among the plurality of bias scan lines GBL, one first emission control line EL1 from among the plurality of first emission control lines EL1, one second emission control line EL2 from among the plurality of second emission control lines EL2, and one data line DL from among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be disposed in the non-display area NDA.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see FIG. 7) through a semiconductor process. For example, the plurality of scan transistors and the plurality of light-emitting transistors may be formed of CMOS, but the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed of CMOS, but the present disclosure is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), and/or aluminum (Al).

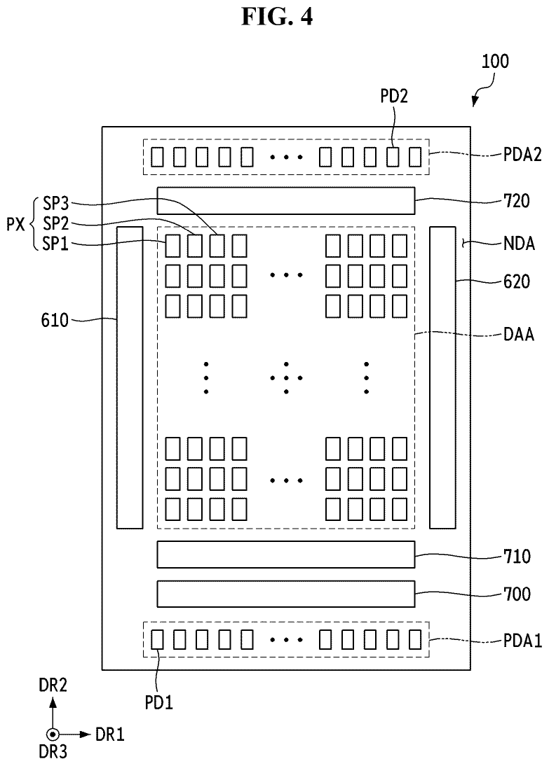

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board (FPCB) with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data DATA and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed of CMOS, but the present disclosure is not limited thereto. Each of the timing control circuit 400 and the power supply circuit 500 may be disposed between the data driver 700 and the first pad portion PDA1 (see FIG. 4).

FIG. 3 is an equivalent circuit diagram of a first sub-pixel according to one or more embodiments.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 includes a plurality of transistors T1 to T6, a light-emitting element LE, a first capacitor CP1, and a second capacitor CP2.

The light-emitting element LE emits light in response to a driving current (or a source-drain current) flowing through the channel of the first transistor T1. The emission amount of the light-emitting element LE may be proportional to the driving current. The light-emitting element LE may be disposed between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode (OLED) including a first electrode, a second electrode, and an organic light-emitting layer disposed between the first electrode and the second electrode, but the present disclosure is not limited thereto. For example, the light-emitting element LE may be an inorganic light-emitting element including a first electrode, a second electrode, and an inorganic semiconductor disposed between the first electrode and the second electrode, in which case the light-emitting element LE may be a micro light-emitting diode.

The first transistor T1 may be a driving transistor that controls the driving current flowing between the source electrode and the drain electrode thereof according to a voltage applied to the gate electrode thereof. The first transistor T1 includes a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 is turned on by the write control signal of the write control line GCL to connect the first node N1 to the second node N2. For this reason, when the gate electrode and the source electrode of the first transistor T1 are connected, the first transistor T1 may operate like a diode (e.g., the first transistor T1 may be diode-connected). The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 includes a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 (e.g., the first node N1) and the second driving voltage line VDL. The second capacitor CP2 includes one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors CP1 and CP2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating an example of a display panel according to one or more embodiments.

Referring to FIG. 4, the display area DAA of the display panel 100 according to one or more embodiments includes the plurality of pixels PX arranged in a matrix form. The non-display area NDA of the display panel 100 according to one or more embodiments includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on the left side of the display area DAA, and the emission driver 620 may be disposed on the right side of the display area DAA. However, the present disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2. The first pad portion PDA1 may be disposed outside the data driver 700 in the second direction DR2. That is, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board (PCB) made of a rigid material or a flexible printed circuit board (FPCB) made of a flexible material.

The second pad portion PDA2 may be disposed on the fourth side of the display area DAA. For example, the second pad portion PDA2 may be disposed on the other side of the display area DAA in the second direction DR2. The second pad portion PDA2 may be disposed outside the second distribution circuit 720 in the second direction DR2. That is, the second pad portion PDA2 may be disposed closer to the edge of the display panel 100 than the second distribution circuit 720.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA. The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. That is, the second distribution circuit 720 may be disposed on the upper side of the display area DAA.

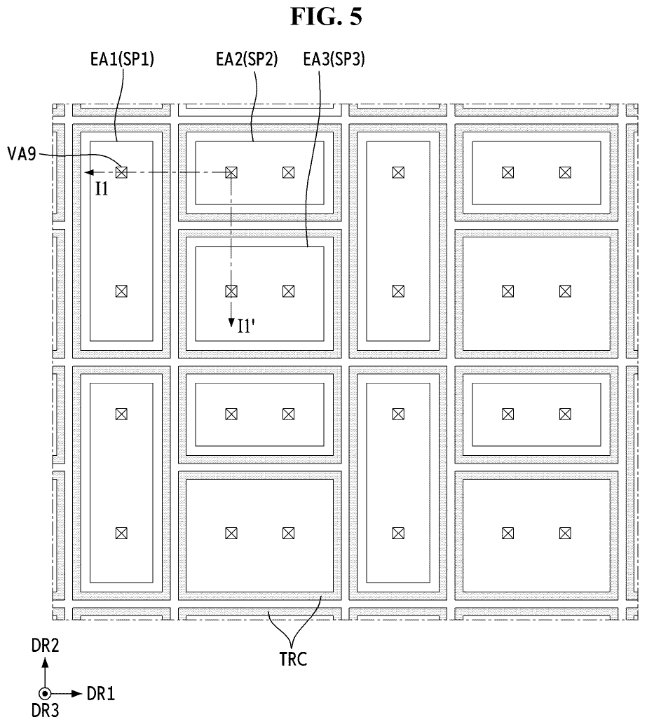

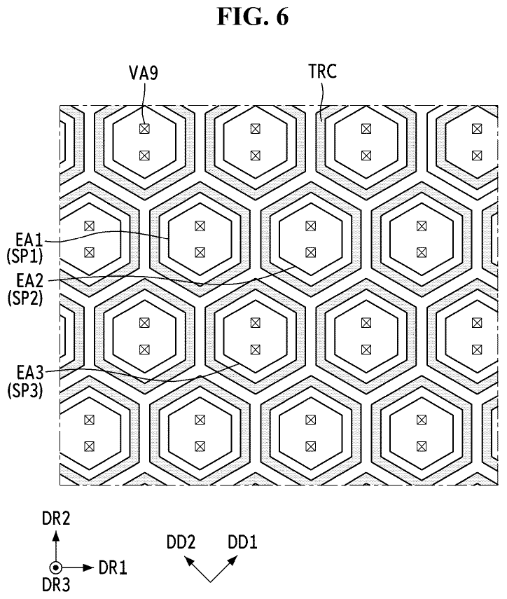

FIGS. 5 and 6 are layout diagrams illustrating examples of the display area of FIG. 4.

Referring to FIGS. 5 and 6, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have a polygonal, circular, elliptical, or atypical shape in a plan view.

The maximum length of the first emission area EA1 in the first direction DR1 may be less than the maximum length of the second emission area EA2 in the first direction DR1 and the maximum length of the third emission area EA3 in the first direction DR1. The maximum length of the second emission area EA2 in the first direction DR1 and the maximum length of the third emission area EA3 in the first direction DR1 may be substantially the same.

The maximum length of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be less than the maximum length of the third emission area EA3 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have, in a plan view, a hexagonal shape formed of six straight lines as shown in FIG. 6, but the present disclosure is not limited thereto. The first emission area EA1, the second emission area EA2, and the third emission area EA3 may have a polygonal shape other than a hexagon, a circular shape, an elliptical shape, and/or an atypical shape in a plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

Alternatively, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light that has passed through a first color filter CF1 (see FIG. 7) from among the light emitted from the first emission area EA1, the second sub-pixel SP2 may emit second light that has passed through a second color filter CF2 (see FIG. 7) from among the light emitted from the second emission area EA2, and the third sub-pixel SP3 may emit third light that has passed through a third color filter CF3 (see FIG. 7) from among the light emitted from the third emission area EA3. Here, the first light may be light of a blue wavelength band, the second light may be light of a green wavelength band, and the third light may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

It is exemplified in FIGS. 5 and 6 that each of the plurality of pixels PX includes three emission areas EA1, EA2, and EA3, but the present disclosure is not limited thereto. That is, each of the plurality of pixels PX may include four emission areas.

In addition, the layout of the emission areas of the plurality of pixels PX is not limited to those illustrated in FIGS. 5 and 6. For example, the emission areas of the plurality of pixels PX may be disposed in a stripe structure in which the emission areas are arranged along the first direction DR1, a PENTILE® structure in which the emission areas are arranged in a diamond shape, or a hexagonal structure in which the emission areas having, in a plan view, a hexagonal shape are arranged as shown in FIG. 6. PENTILE® is a registered trademark of Samsung Display Co., Ltd., Republic of Korea.

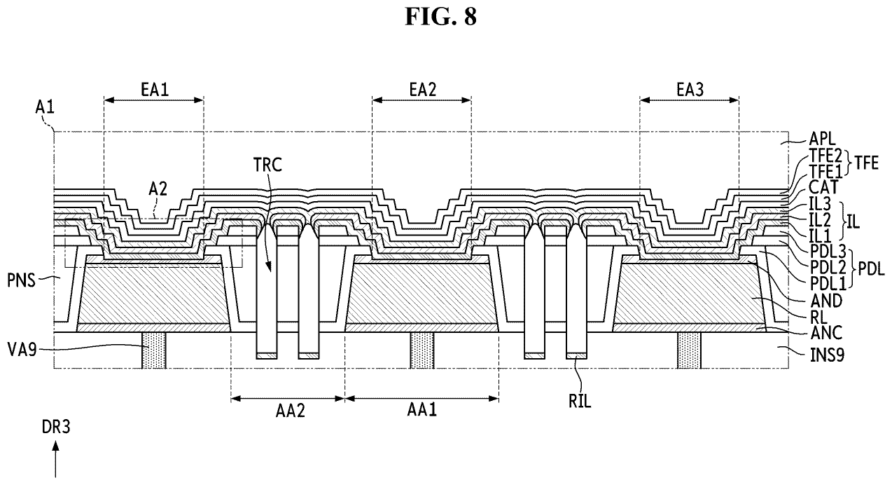

FIG. 7 is a cross-sectional view illustrating an example of a display panel taken along the line 11-11′ of FIG. 5. FIG. 8 is a cross-sectional view specifically showing area A1 of FIG. 7.

Referring to FIGS. 7 and 8, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, and/or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating film SINS1 may be disposed on the semiconductor substrate SSUB. The first semiconductor insulating film SINS1 may be formed of silicon carbonitride (SiCN) and/or a silicon oxide (SiOx)-based inorganic film, but the present disclosure is not limited thereto.

A second semiconductor insulating film SINS2 may be disposed on the first semiconductor insulating film SINS1. The second semiconductor insulating film SINS2 may be formed of a silicon oxide (SiOx)-based inorganic film, but the present disclosure is not limited thereto.

The plurality of contact terminals CTE may be disposed on the second semiconductor insulating film SINS2. Each of the plurality of contact terminals CTE may be connected to one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but the present disclosure is not limited thereto.

The semiconductor substrate SSUB may be replaced with a glass substrate and/or a polymer resin substrate such as polyimide. In this case, thin film transistors may be disposed on the glass substrate and/or the polymer resin substrate. The glass substrate may be a rigid substrate that does not bend, and the polymer resin substrate may be a flexible substrate that can be bent or curved.

The light-emitting element backplane EBP includes a plurality of conductive layers ML1 to ML8, a plurality of vias VA1 to VA9, and a plurality of insulating films INS1 to INS9. In addition, the light-emitting element backplane EBP includes the plurality of insulating films INS1 to INS9 disposed between the contact terminals and the connection electrodes ANC.

The first to eighth conductive layers ML1 to ML8 serve to connect the plurality of contact terminals CTE exposed from the semiconductor backplane SBP to thereby implement the circuit of the first sub-pixel SP1 shown in FIG. 3. For example, the first to sixth transistors T1 to T6 are merely formed in the semiconductor backplane SBP, and the connection of the first to sixth transistors T1 to T6 and the first and second capacitors CP1 and CP2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light-emitting element LE is also accomplished through the first to eighth conductive layers ML1 to ML8.

The first insulating film INS1 may be disposed on the semiconductor backplane SBP. Each of the first vias VA1 may penetrate the first insulating film INS1 and may be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and may be connected to the exposed first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and may be connected to the exposed second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and may be connected to the exposed third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and may be connected to the exposed fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and may be connected to the exposed fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and may be connected to the exposed sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and may be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The first to eighth vias VA1 to VA8 may be made of substantially the same material. First to eighth insulating films INS1 to INS8 may be formed of a silicon oxide (SiOx)-based inorganic film, but the present disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1,360 Å. The thickness of each of the second conductive layer ML2, the third conductive layer ML3, the fourth conductive layer ML4, the fifth conductive layer ML5, and the sixth conductive layer ML6 may be approximately 1,440 Å. The thickness of each of the first via VA1, the second via VA2, the third via VA3, the fourth via VA4, the fifth via VA5, and the sixth via VA6 may be approximately 1,150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be about 4,000 Å to about 9,000 Å. The thickness of each of the seventh via VA7 and the eighth via VA8 may be about 6,000 Å to about 7,000 Å.

A ninth insulating film INS9 may be disposed on the eighth insulating film INS8 and the eighth conductive layer ML8. The ninth insulating film INS9 may be formed of a silicon oxide (SiOx)-based inorganic film, but the present disclosure is not limited thereto.

Each of the ninth vias VA9 may penetrate the ninth insulating film INS9 and may be connected to the exposed eighth conductive layer ML8. The ninth vias VA9 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The thickness of the ninth via VA9 may be about 6,000 Å to about 7,000 Å.

The display element layer EML may be disposed on the light-emitting element backplane EBP. The display element layer EML may include a plurality of connection electrodes ANC, a plurality of reflective electrodes RL, a planarization film PNS, a pixel defining film PDL, a plurality of first electrodes AND, a light-emitting stack IL, a second electrode CAT, and a plurality of trenches TRC.

Further, the display element layer EML may include the first emission area EA1, the second emission area EA2, and the third emission area EA3. Each of the first emission area EA1, the second emission area EA2, and the third emission area EA3 may be an area in which the first electrode AND, the light-emitting stack IL, and the second electrode CAT are sequentially stacked. Each of the first emission area EA1, the second emission area EA2, and the third emission area EA3 may be an area in which the light-emitting element LE including the first electrode AND, the light-emitting stack IL, and the second electrode CAT is disposed. Each of the first emission area EA1, the second emission area EA2, and the third emission area EA3 may be partitioned by a first pixel defining film PDL1.

The ninth insulating film INS9 may include first areas AA1 overlapping the plurality of connection electrodes ANC and a second area AA2 disposed around the first areas AA1.

The plurality of connection electrodes ANC may be respectively disposed on the first areas AA1 of the ninth insulating film INS9. Each of the plurality of connection electrodes ANC may be disposed on the first area AA1 corresponding thereto. The plurality of connection electrodes ANC may be formed of titanium nitride (TiN) and/or a transparent conductive oxide. For example, the transparent conductive oxide may be indium tin oxide (ITO) and/or indium zinc oxide (IZO), but the present disclosure is not limited thereto. The thickness of each of the plurality of connection electrodes ANC may be approximately 600 Å.

The plurality of reflective electrodes RL may be respectively disposed on the plurality of connection electrodes ANC. Each of the plurality of reflective electrodes RL may be disposed on the connection electrode ANC corresponding thereto. The plurality of reflective electrodes RL may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, each of the plurality of reflective electrodes RL may include aluminum (Al) with high reflectivity. The thickness of each of the plurality of reflective electrodes RL may be approximately 12,000 Å.

Each of the light-emitting elements LE may include the first electrode AND, the light-emitting stack IL, and the second electrode CAT.

The first electrode AND of each of the light-emitting elements LE may be disposed on the reflective electrode RL corresponding thereto. The first electrode AND of each of the light-emitting elements LE may be connected to the drain region DA or the source region SA of the pixel transistor PTR through the reflective electrode RL, the connection electrode ANC, the first to ninth vias VA1 to VA9, the first to eighth conductive layers ML1 to ML8, and the contact terminal CTE. The first electrode AND of each of the light-emitting elements LE may be formed of copper (Cu), aluminum (Al), tungsten (W), molybdenum (Mo), chromium (Cr), gold (Au), titanium (Ti), nickel (Ni), and/or neodymium (Nd), and/an alloy including one or more of them, or a transparent conductive oxide. For example, the first electrode AND of each of the light-emitting elements LE may include titanium nitride (TiN), indium tin oxide (ITO), or indium zinc oxide (IZO), but the present disclosure is not limited thereto.

The thickness of the first electrode AND of each of the light-emitting elements LE may be approximately 100 Å or less. For example, the thickness of the first electrode AND of each of the light-emitting elements LE may be approximately 70 Å to 80 Å.

The connection electrode ANC, the reflective electrode RL, and the first electrode AND may be sequentially stacked. Because the connection electrode ANC, the reflective electrode RL, and the first electrode AND are patterned at once using a single mask, the side surface of the connection electrode ANC, the side surface of the reflective electrode RL, and the side surface of the first electrode AND may be aligned with each other. In addition, because the plurality of connection electrodes ANC, the plurality of reflective electrodes RL, and the plurality of first electrodes AND are formed at once, the number of mask processes may be reduced compared to the case in which each of the plurality of first electrodes AND is connected to the exposed reflective electrode RL through a contact hole penetrating an insulating film, thereby reducing manufacturing cost and increasing manufacturing efficiency.

The pixel defining film PDL may be disposed on the first electrode AND of each of the light-emitting elements LE and may expose a portion of the first electrode AND. The pixel defining film PDL may partition the first emission areas EA1, the second emission areas EA2, and the third emission areas EA3. The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel defining film PDL may include first to third pixel defining films PDL1, PDL2, and PDL3.

The first pixel defining film PDL1 may be disposed on the first electrode AND of each of the light-emitting elements LE. A portion of the first electrode AND may be exposed without being covered by the first pixel defining film PDL1.

The planarization film PNS is a film for planarizing a stepped portion caused by the plurality of connection electrodes ANC, the plurality of reflective electrodes RL, and the plurality of first electrodes AND. The planarization film PNS may be disposed between the connection electrodes ANC adjacent in the first direction DR1 or the second direction DR2. The planarization film PNS may be disposed between the reflective electrodes RL adjacent in the first direction DR1 or the second direction DR2. The planarization film PNS may be disposed between the first electrodes AND adjacent in the first direction DR1 or the second direction DR2. The planarization film PNS may be disposed on the first pixel defining film PDL1 disposed on the second area AA2 of the ninth insulating film INS9.

The second pixel defining film PDL2 may be disposed on the first pixel defining film PDL1 and the planarization film PNS, and the third pixel defining film PDL3 may be disposed on the second pixel defining film PDL2. The first pixel defining film PDL1 and the third pixel defining film PDL3 may be formed as a silicon nitride (SiNₓ)-based inorganic film, and the second pixel defining film PDL2 and the planarization film PNS may be formed as a silicon oxide (SiOx)-based inorganic film. Because the first pixel defining film PDL1 is formed of a material different from that of the planarization film PNS, it may serve as a stopper in a chemical mechanical polishing process of the planarization film PNS.

Each of the thickness of the first pixel defining film PDL1, the thickness of the second pixel defining film PDL2, and the thickness of the third pixel defining film PDL3 may be approximately 500 Å, but the present disclosure is not limited thereto.

When the first pixel defining film PDL1, the second pixel defining film PDL2, and the third pixel defining film PDL3 are formed as one pixel defining film, the height of the one pixel defining film increases, so that the second electrode CAT and a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

In order to reduce or prevent the likelihood of the second electrode CAT and the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, a portion of the first pixel defining film PDL1 may be exposed without being covered by the second pixel defining film PDL2, and a portion of the second pixel defining film PDL2 may be exposed without being covered by the third pixel defining film PDL3. The exposed portion of the first pixel defining film PDL1 may be the edge of the first pixel defining film PDL1, and the exposed portion of the second pixel defining film PDL2 may be the edge of the second pixel defining film PDL2.

Further, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 or the second direction DR2.

Each of the plurality of trenches TRC may penetrate the first pixel defining film PDL1, the planarization film PNS, the second pixel defining film PDL2, and the third pixel defining film PDL3. Further, the ninth insulating film INS9 may be partially recessed at each of the plurality of trenches TRC.

At least one trench TRC may be disposed between adjacent emission areas EA1, EA2, and EA3. Although FIGS. 7 and 8 illustrate that two trenches TRC are disposed between the neighboring emission areas EA1, EA2, and EA3, the present disclosure is not limited thereto.

The light-emitting stack IL may include a plurality of stack layers IL1, IL2, and IL3. FIGS. 7 and 8 illustrate that the light-emitting stack IL has a three-tandem structure including a first stack layer IL1, a second stack layer IL2, and a third stack layer IL3, but the present disclosure is not limited thereto. For example, the light-emitting stack IL may have a two-tandem structure including two stack layers.

In the three-tandem structure, the light-emitting stack IL may have a tandem structure including a plurality of stack layers IL1, IL2, and IL3 that emit different lights. For example, the light-emitting stack IL may include the first stack layer IL1 that emits first light, the second stack layer IL2 that emits third light, and the third stack layer IL3 that emits second light. The first stack layer IL1, the second stack layer IL2, and the third stack layer IL3 may be sequentially stacked.

The first stack layer IL1 may have a structure in which a first hole transport layer, a first organic light-emitting layer that emits the first light, and a first electron transport layer are sequentially stacked. The second stack layer IL2 may have a structure in which a second hole transport layer, a second organic light-emitting layer that emits the third light, and a second electron transport layer are sequentially stacked. The third stack layer IL3 may have a structure in which a third hole transport layer, a third organic light-emitting layer that emits the second light, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an n-type charge generation layer that supplies electrons to the first stack layer IL1 and a p-type charge generation layer that supplies holes to the second stack layer IL2. The n-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an n-type charge generation layer that supplies electrons to the second stack layer IL2 and a p-type charge generation layer that supplies holes to the third stack layer IL3.

The first stack layer IL1 may be disposed on the first electrodes AND and the pixel defining film PDL. A remaining film RIL made of the same material as the first stack layer IL1 may be disposed on the bottom surface of each of the trenches TRC. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the remaining film RIL and the second stack layer IL2 in each trench TRC. The third stack layer IL3 may be disposed on the second stack layer IL2. The third stack layer IL3 is not cut off by the trench TRC and may be disposed to cover the second stack layer IL2 in each of the trenches TRC.

In the three-tandem structure, each of the plurality of trenches TRC may be a structure for cutting off the first and second charge generation layers of the display element layer EML because a current may flow through the first and second charge generation layers between the adjacent sub-pixels SP1, SP2, and SP3. In addition, in the two-tandem structure, each of the plurality of trenches TRC may be a structure for cutting off a charge generation layer disposed between a lower stack layer and an upper stack layer because a current may flow through the charge generation layer.

In order to stably cut off the first and second charge generation layers of the display element layer EML between the adjacent emission areas EA1, EA2, and EA3, the height of each of the plurality of trenches TRC may be greater than the sum of the thickness of the first pixel defining film PDL1, the thickness of the second pixel defining film PDL2, the thickness of the third pixel defining film PDL3, and the thickness of the planarization film PNS. The height of each of the plurality of trenches TRC refers to the length of each of the plurality of trenches TRC in the third direction DR3.

In order to cut off the first and second charge generation layers of the display element layer EML between the adjacent emission areas EA1, EA2, and EA3, another structure may be used instead of the trench TRC. For example, instead of the trench TRC, a reverse tapered partition wall may be disposed on the pixel defining film PDL.

The second electrode CAT may be disposed on the light-emitting stack IL.

The second electrode CAT may be disposed on the third stack layer IL3 in each of the plurality of trenches TRC. The second electrode CAT may be formed of a transparent conductive material (TCO), and/or a semi-transmissive conductive material such as magnesium (Mg), silver (Ag), and/or an alloy of magnesium (Mg) and silver (Ag). In this case, light emission efficiency in each of the first to third sub-pixels SP1, SP2, and SP3 may be increased due to a micro-cavity effect.

In order to apply a micro-cavity, a first resonance distance between the first organic light-emitting layer of the first stack layer IL1 and the reflective electrode RL may be set in consideration of the main peak wavelength of the first light. In addition, a second resonance distance between the second organic light-emitting layer of the second stack layer IL2 and the reflective electrode RL may be set in consideration of the main peak wavelength of the second light. In addition, a third resonance distance between the third organic light-emitting layer of the third stack layer IL3 and the reflective electrode RL may be set in consideration of the main peak wavelength of the third light. Therefore, because a separate step layer for setting the first resonance distance, the second resonance distance, and the third resonance distance may be omitted, the number of masks for forming step layers through a photolithography process may be reduced, thereby reducing manufacturing cost.

The encapsulation layer TFE may be disposed on the display element layer EML. The encapsulation layer TFE may include at least one inorganic film TFE1 and TFE2 to reduce or prevent oxygen and/or moisture from permeating into the display element layer EML. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxynitride (SiON), and/or silicon oxide (SiOx) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOx) and/or aluminum oxide (AlOx), but the present disclosure is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

An organic film APL may be a layer for increasing the interfacial adhesion between the encapsulation layer TFE and the optical layer OPL. The organic film APL may be an organic film such as acrylic resin, epoxy resin, phenolic resin, polyamide resin, and/or polyimide resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the organic film APL. In one or more other embodiments, the first to third color filters CF1, CF2, and CF3 may be disposed on an adhesive layer.

The first color filter CF1 may overlap the first emission area EA1 of the first sub-pixel SP1. The first color filter CF1 may transmit the first light, i.e., light of a red wavelength band. Thus, the first color filter CF1 may transmit the first light from among light emitted from the light-emitting stack IL of the first emission area EA1.

The second color filter CF2 may overlap the second emission area EA2 of the second sub-pixel SP2. The second color filter CF2 may transmit the second light, i.e., light of a green wavelength band. Thus, the second color filter CF2 may transmit the second light from among light emitted from the light-emitting stack IL of the second emission area EA2.

The third color filter CF3 may overlap the third emission area EA3 of the third sub-pixel SP3. The third color filter CF3 may transmit the third light, i.e., light of a blue wavelength band. Thus, the third color filter CF3 may transmit the third light from among light emitted from the light-emitting stack IL of the third emission area EA3.

The plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Although each of the lenses LNS is illustrated as having a cross-sectional shape that is convex upward, the present disclosure is not limited thereto.

The filling layer FIL may be disposed on the plurality of lenses LNS. The filling layer FIL may have a suitable refractive index (e.g., a predetermined refractive index) such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, and/or polyimide resin.

The cover layer CVL may be disposed on the filling layer FIL. The cover layer CVL may be a glass substrate and/or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be disposed on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the present disclosure is not limited thereto. However, when visibility degradation caused by reflection of external light is sufficiently overcome by the first to third color filters CF1, CF2, and CF3, the polarizing plate POL may be omitted.

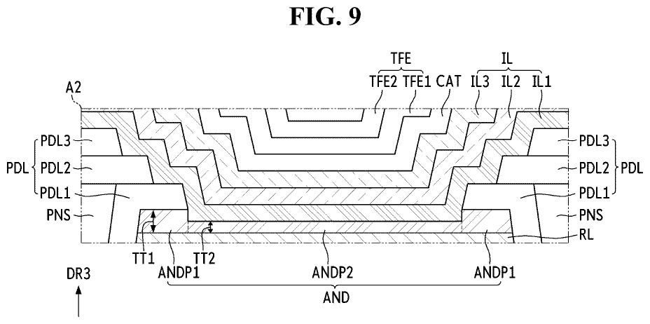

FIG. 9 is a cross-sectional view specifically illustrating an example of an area A2 of FIG. 8.

Referring to FIG. 9, the first electrode AND includes a first portion ANDP1 and a second portion ANDP2.

The first portion ANDP1 of the first electrode AND may be a portion of the first electrode AND that overlaps the first pixel defining film PDL1 in the third direction DR3. The first portion ANDP1 of the first electrode AND may be covered by the first pixel defining film PDL1.

The second portion ANDP2 of the first electrode AND may be a portion of the first electrode AND that does not overlap the first pixel defining film PDL1 in the third direction DR3. The second portion ANDP2 of the first electrode AND may be exposed without being covered by the first pixel defining film PDL1.

A thickness TT2 of the second portion ANDP2 of the first electrode AND may be less than a thickness TT1 of the first portion ANDP1. For example, the thickness TT2 of the second portion ANDP2 of the first electrode AND may be 50 Å or less, and the thickness TT1 of the first portion ANDP1 of the first electrode AND may be 100 Å or less.

Because the thickness TT2 of the second portion ANDP2 of the first electrode AND is less than the thickness TT1 of the first portion ANDP1 of the first electrode AND, the light transmittance of the second portion ANDP2 of the first electrode AND may be higher than the light transmittance of the first portion ANDP1 of the first electrode AND. Accordingly, the proportion of light that resonates between the first electrode AND and the second electrode CAT from among the light emitted from the first organic light-emitting layer of the first stack layer IL1 may increase. Similarly, the proportion of light that resonates between the first electrode AND and the second electrode CAT from among the light emitted from the second organic light-emitting layer of the second stack layer IL2, and the proportion of light that resonates between the first electrode AND and the second electrode CAT from among the light emitted from the third organic light-emitting layer of the third stack layer IL3 may also increase. Therefore, the proportion of light emitted due to an optical micro-cavity between the first electrode AND and the second electrode CAT may increase. Accordingly, the light emission efficiency of the first emission area EA1, the light emission efficiency of the second emission area EA2, and the light emission efficiency of the third emission area EA3 may be improved.

In addition, the side surface of the first pixel defining film PDL1, the side surface of the second pixel defining film PDL2, and the side surface of the third pixel defining film PDL3 may be formed to be inclined. In this case, the step-shaped slope formed by the first pixel defining film PDL1, the second pixel defining film PDL2, and the third pixel defining film PDL3 may become gentle. Therefore, the second electrode CAT and the first encapsulation inorganic film TFE1 disposed on the side surface of the first pixel defining film PDL1, the side surface of the second pixel defining film PDL2, and the side surface of the third pixel defining film PDL3 may be prevented from being cut off due to step coverage.

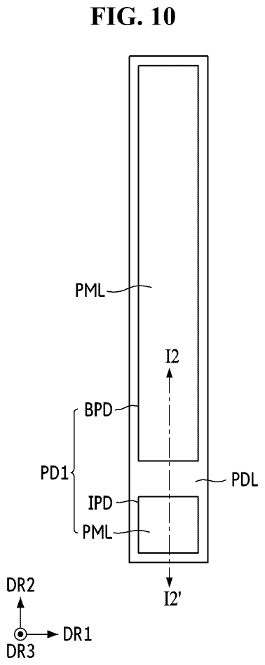

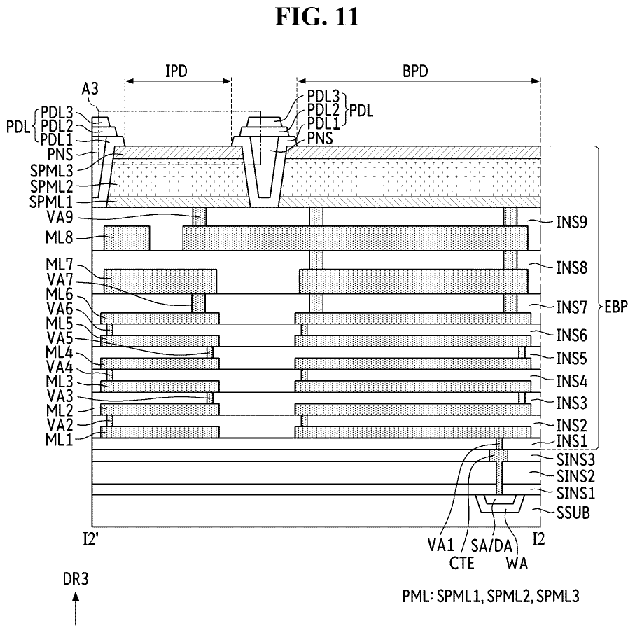

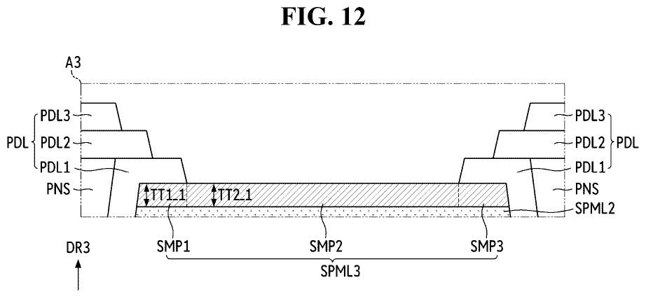

FIG. 10 is a layout diagram illustrating an example of the first pad of the first pad portion of FIG. 4. FIG. 11 is a cross-sectional view illustrating an example of a display panel taken along the line 12-12′ of FIG. 10. FIG. 12 is a plan view specifically illustrating an example of an area A3 of FIG. 11.

Referring to FIGS. 10-12, each of the first pads PD1 includes a first sub-pad BPD and a second sub-pad IPD. Both the first sub-pad BPD and the second sub-pad IPD may be electrically connected to a pad or bump of the circuit board 300 through a conductive adhesive member. In addition, the second sub-pad IPD may be a pad connected to a jig or probe pin during an inspection process or connected to a circuit board for inspection.

The area of the first sub-pad BPD may be larger than the area of the second sub-pad IPD. The length of the first sub-pad BPD in the first direction DR1 may be substantially the same as the length of the second sub-pad IPD in the first direction DR1. The length of the first sub-pad BPD in the second direction DR2 may be greater than the length of the second sub-pad IPD in the second direction DR2.

Each of the first sub-pad BPD and the second sub-pad IPD may include a pad conductive layer PML. The pad conductive layer PML may include a first sub-pad conductive layer SPML1, a second sub-pad conductive layer SPML2, and a third sub-pad conductive layer SPML3.

The first sub-pad conductive layer SPML1 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them, and/or a transparent conductive oxide. For example, the first sub-pad conductive layer SPML1 may include the same material as the plurality of connection electrodes ANC. The first sub-pad conductive layer SPML1 may be formed of titanium nitride (TiN) and/or a transparent conductive oxide.

The second sub-pad conductive layer SPML2 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the second sub-pad conductive layer SPML2 may include the same material as the plurality of reflective electrodes RL. The second sub-pad conductive layer SPML2 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the second sub-pad conductive layer SPML2 may include aluminum (Al) with high reflectivity.

The third sub-pad conductive layer SPML3 may be formed of copper (Cu), aluminum (Al), tungsten (W), molybdenum (Mo), chromium (Cr), gold (Au), titanium (Ti), nickel (Ni), and/or neodymium (Nd), and/an alloy including one or more of them, and/or a transparent conductive oxide. For example, the third sub-pad conductive layer SPML3 may include the same material as the plurality of first electrodes AND. For example, the third sub-pad conductive layer SPML3 may include titanium nitride (TiN), indium tin oxide (ITO), and/or indium zinc oxide (IZO), but the present disclosure is not limited thereto.

The thickness of the first sub-pad conductive layer SPML1 may be less than the thickness of the second sub-pad conductive layer SPML2. The thickness of the third sub-pad conductive layer SPML3 may be less than the thickness of the second sub-pad conductive layer SPML2. The thickness of the third sub-pad conductive layer SPML3 may be less than the thickness of the first sub-pad conductive layer SPML1. For example, the thickness of the first sub-pad conductive layer SPML1 may be approximately 600 Å, the thickness of the second sub-pad conductive layer SPML2 may be approximately 850 Å, and the thickness of the third sub-pad conductive layer SPML3 may be approximately 100 Å or less.

The pad conductive layer PML of the first sub-pad BPD and the pad conductive layer PML of the second sub-pad IPD are disposed to be spaced (e.g., spaced apart) from each other, but both of them may be connected to the eighth conductive layer ML8 through the ninth via VA9 penetrating the ninth insulating film INS9. The first sub-pad conductive layer SPML1 of the first sub-pad BPD and the first sub-pad conductive layer SPML1 of the second sub-pad IPD may be connected to the eighth conductive layer ML8 through the ninth via VA9 penetrating the ninth insulating film INS9. Therefore, the pad conductive layer PML of the first sub-pad BPD and the pad conductive layer PML of the second sub-pad IPD may have substantially the same potential. Accordingly, the pad conductive layer PML of the first sub-pad BPD and the pad conductive layer PML of the second sub-pad IPD may be electrically connected to the contact terminal CTE of the semiconductor substrate SSUB.

As shown in FIGS. 10-12, the pad conductive layer PML of the first sub-pad BPD and the pad conductive layer PML of the second sub-pad IPD are separated or distinguished from each other, so that the pad conductive layer PML of the first sub-pad BPD may not be damaged or broken even if the pad conductive layer PML of the second sub-pad IPD is damaged or broken by a jig or a probe pin during an inspection process. That is, by physically separating the second sub-pad IPD used in the inspection process from the first sub-pad BPD connected to the circuit board 300, the pad conductive layer PML of the first sub-pad BPD may be stably connected to the circuit board 300 even when the pad conductive layer PML of the second sub-pad IPD is damaged.

In addition, as shown in FIG. 12, the third sub-pad conductive layer SPML3 includes a first portion SMP1 and a second portion SMP2.

The first portion SMP1 of the third sub-pad conductive layer SPML3 may be a portion of the third sub-pad conductive layer SPML3 that overlaps the first pixel defining film PDL1 in the third direction DR3. The first portion SMP1 of the third sub-pad conductive layer SPML3 may be covered by the first pixel defining film PDL1.

The second portion SMP2 of the third sub-pad conductive layer SPML3 may be a portion of the third sub-pad conductive layer SPML3 that does not overlap the first pixel defining film PDL1 in the third direction DR3. The second portion SMP2 of the third sub-pad conductive layer SPML3 may be exposed without being covered by the first pixel defining film PDL1.

In the emission areas EA1, EA2, and EA3, in order to increase the light transmittance of the first electrode AND, the thickness TT2 of the second portion ANDP2 of the first electrode AND is formed to be less than the thickness TT1 of the first portion ANDP1 of the first electrode AND, but in the first pad PD1, there is no need to reduce the thickness of the third sub-pad conductive layer SPML3 when considering contact resistance. Therefore, a thickness TT1_1 of the first portion SMP1 of the third sub-pad conductive layer SPML3 may be substantially the same as a thickness TT2_1 of the second portion SMP2 of the third sub-pad conductive layer SPML3.

In addition, the thickness TT1_1 of the first portion SMP1 and the thickness TT2_1 of the second portion SMP2 of the third sub-pad conductive layer SPML3 may be substantially the same as the thickness TT1 of the first portion ANDP1 of each of the plurality of first electrodes AND. In addition, the thickness TT1_1 of the first portion SMP1 and the thickness TT2_1 of the second portion SMP2 of the third sub-pad conductive layer SPML3 may be greater than the thickness TT2 of the second portion ANDP2 of each of the plurality of first electrodes AND.

The description of the second pad PD2 shown in FIG. 4 is substantially the same as the description of the first pad PD1 provided with reference to FIGS. 10-12 and therefore the description of the second pad PD2 will be omitted.

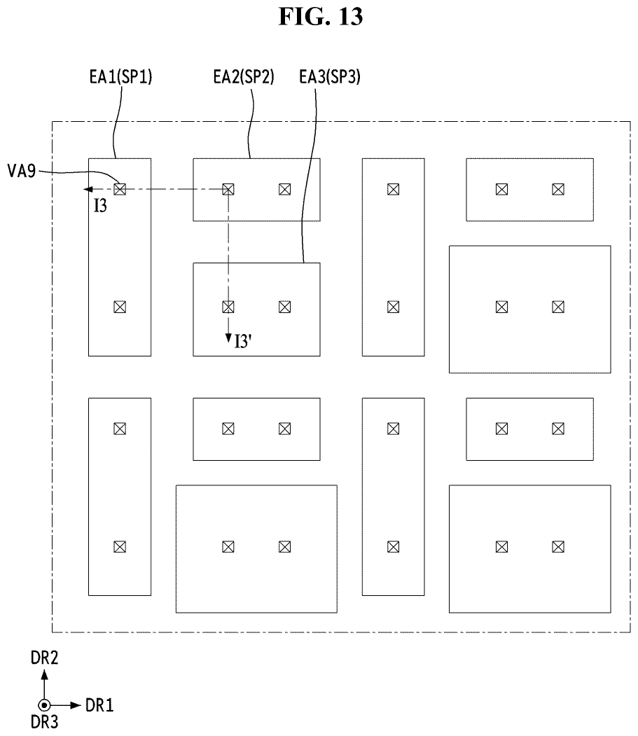

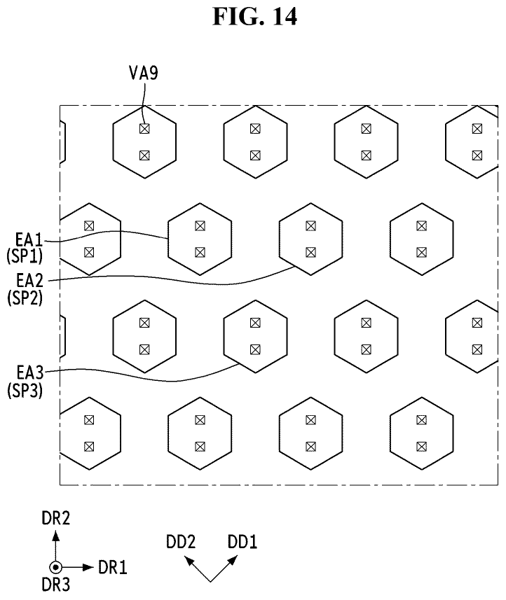

FIGS. 13 and 14 are layout diagrams illustrating another example of the display area of FIG. 4.

The embodiment of FIGS. 13 and 14 differs from the embodiment of FIGS. 5 and 6 in that the trench TRC is omitted. In the embodiment of FIGS. 13 and 14, the description focuses on differences from the embodiments of FIGS. 5 and 6.

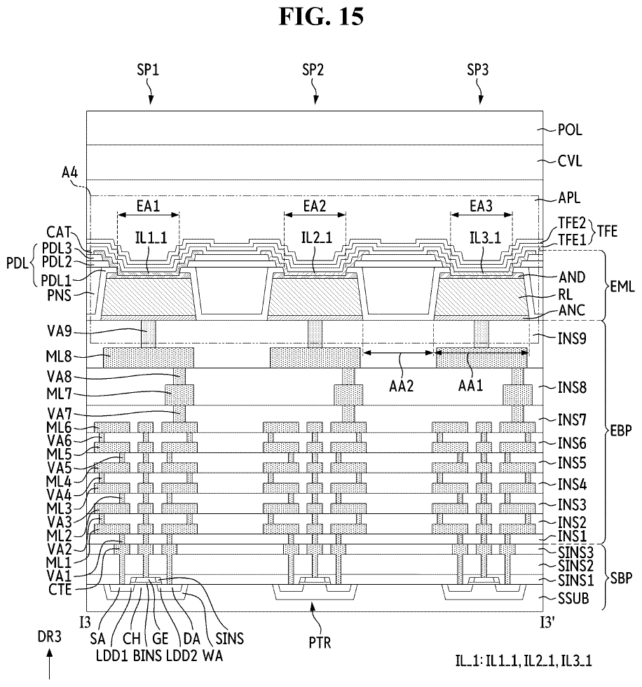

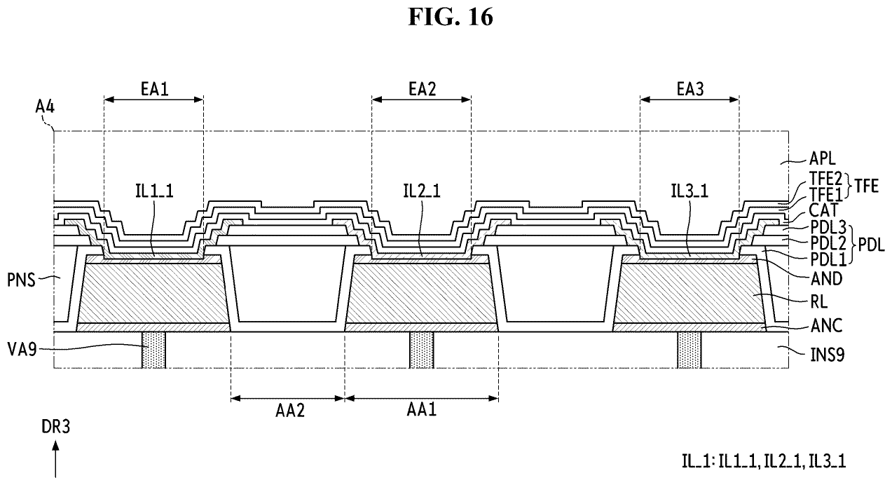

Referring to FIGS. 13 and 14, the first emission area EA1 includes a first light-emitting layer IL1_1 (see FIGS. 15 and 16) that emits the first light, the second emission area EA2 includes a second light-emitting layer IL2_1 (see FIGS. 15 and 16) that emits the second light, and the third emission area EA3 includes a third light-emitting layer IL3_1 (see FIGS. 15 and 16) that emits the third light. The light-emitting stack IL (see FIGS. 7 and 8) includes the first charge generation layer between the first stack layer IL1 and the second stack layer IL2, and the second charge generation layer between the second stack layer IL2 and the third stack layer IL3, but in the embodiment of FIGS. 13 and 14, one light-emitting layer is disposed in each of the emission areas EA1, EA2, and EA3. As a result, in the embodiment of FIGS. 13 and 14, it is not necessary to cut off the first charge generation layer and the second charge generation layer to prevent a current from flowing through the first charge generation layer and the second charge generation layer. Therefore, the trench TRC may be omitted in the embodiment of FIGS. 13 and 14.

FIG. 15 is a cross-sectional view illustrating an example of the display panel taken along the line 13-13′ of FIG. 13. FIG. 16 is a cross-sectional view specifically illustrating an example of an area A4 of FIG. 15.

The embodiment of FIGS. 15 and 16 differs from the embodiment of FIGS. 7 and 8 in that the trench TRC, the first to third color filters CF1, CF2, and CF3, the lenses LNS, and the filling layer FIL are omitted, and the light-emitting stack IL is replaced with the first light-emitting layer IL1_1, the second light-emitting layer IL2_1, and the third light-emitting layer IL3_1.

Referring to FIGS. 15 and 16, the first light-emitting layer IL1_1 may be disposed on the first electrode AND that is exposed without being covered by the first pixel defining film PDL1 in the first emission area EA1. The first light-emitting layer IL1_1 may be disposed on the first pixel defining film PDL1, the second pixel defining film PDL2, and the third pixel defining film PDL3.

The second light-emitting layer IL2_1 may be disposed on the first electrode AND that is exposed without being covered by the first pixel defining film PDL1 in the second emission area EA2. The second light-emitting layer IL2_1 may be disposed on the first pixel defining film PDL1, the second pixel defining film PDL2, and the third pixel defining film PDL3.

The third light-emitting layer IL3_1 may be disposed on the first electrode AND that is exposed without being covered by the first pixel defining film PDL1 in the third emission area EA3. The third light-emitting layer IL3_1 may be disposed on the first pixel defining film PDL1, the second pixel defining film PDL2, and the third pixel defining film PDL3.

The first light-emitting layer IL1_1, the second light-emitting layer IL2_1, and the third light-emitting layer IL3_1 may be disposed to be spaced (e.g., spaced apart) from each other.

Because the first light-emitting layer IL1_1 of the first emission area EA1 emits the first light, the second light-emitting layer IL2_1 of the second emission area EA2 emits the second light, and the third light-emitting layer IL3_1 of the third emission area EA3 emits the third light, the first to third color filters CF1, CF2, and CF3, the plurality of lenses LNS, and the filling layer FIL of the optical layer OPL may be omitted.

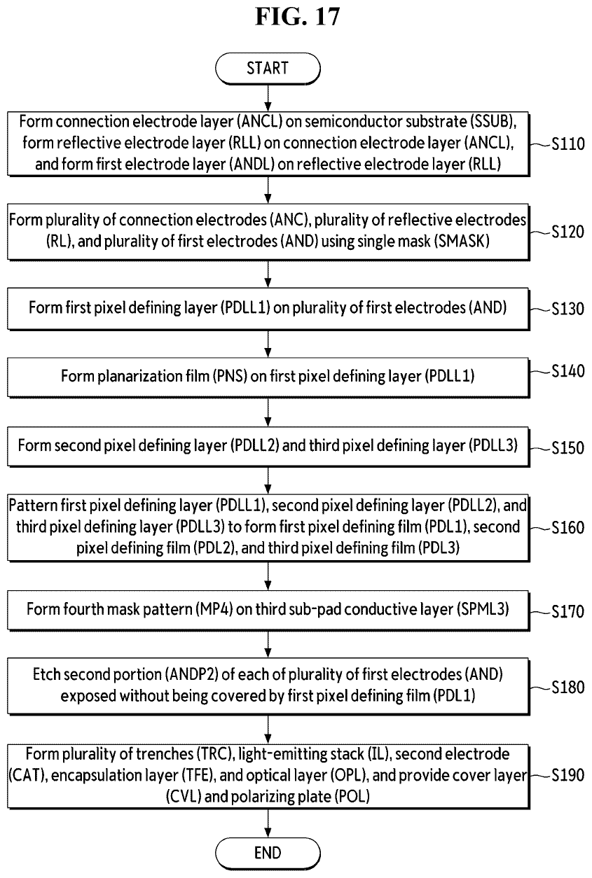

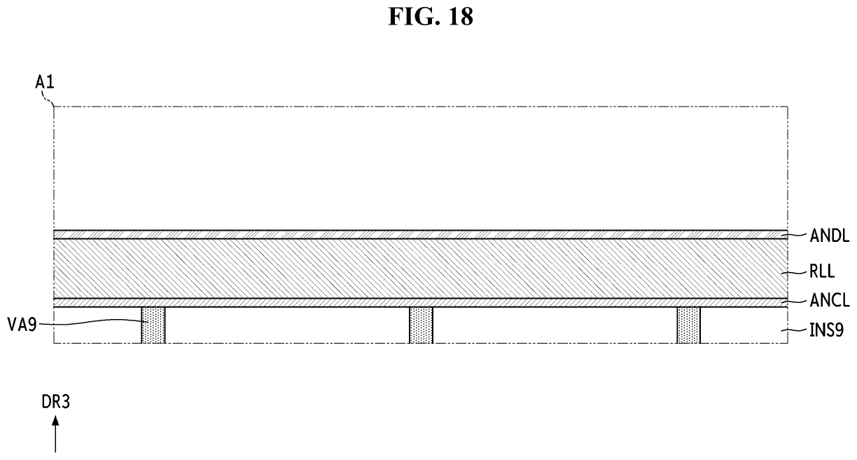

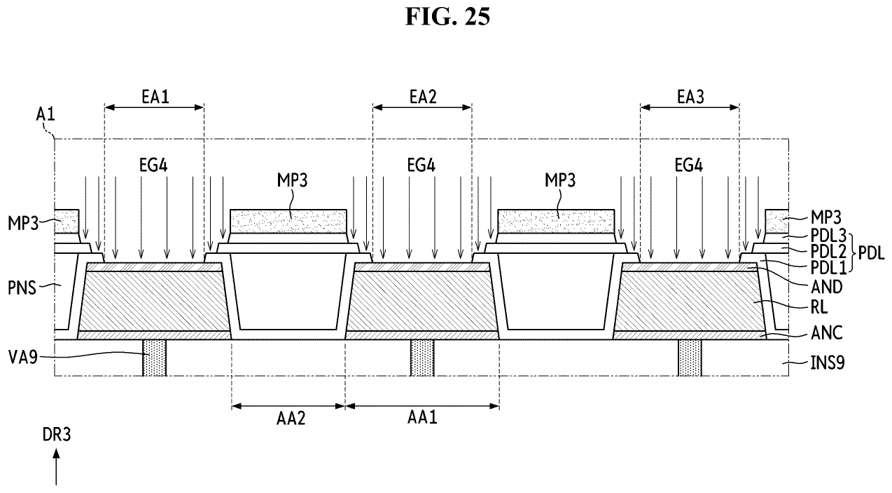

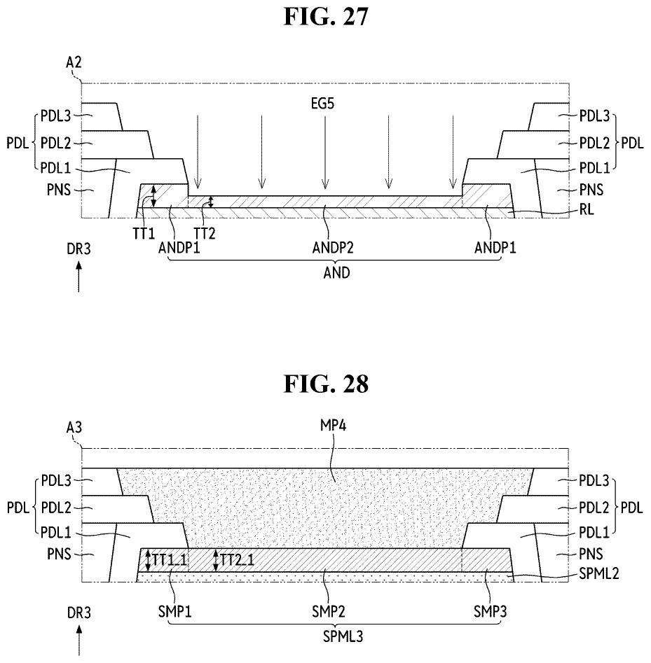

FIG. 17 is a flowchart illustrating a method for manufacturing a display panel according to one or more embodiments. FIGS. 18-26 are cross-sectional views specifically showing the area A1 to describe a method for manufacturing a display panel according to one or more embodiments. FIG. 27 is a cross-sectional view specifically showing the area A2 to describe a method for manufacturing a display panel according to one or more embodiments. FIG. 28 is a cross-sectional view specifically showing the area A3 to describe a method for manufacturing a display panel according to one or more embodiments.

Hereinafter, a method for manufacturing a display panel according to one or more embodiments will be described in detail with reference to FIG. 7 and FIGS. 17-28.

Firstly, as shown in FIGS. 7 and 18, the semiconductor backplane SBP is formed on the semiconductor substrate SSUB, a connection electrode layer ANCL is formed on the semiconductor backplane SBP, a reflective electrode layer RLL is formed on the connection electrode layer ANCL, and a first electrode layer ANDL is formed on the reflective electrode layer RLL (S110 of FIG. 17).

The first to eighth conductive layers ML1 to ML8, the first to ninth vias VA1 to VA9, and the first to ninth insulating films INS1 to INS9 of the light-emitting element backplane EBP are formed on the semiconductor substrate SSUB.

Specifically, the first insulating film INS1 is formed on the semiconductor substrate SSUB, the first vias VA1 respectively connected to the contact terminals CTE of the semiconductor substrate SSUB while penetrating the first insulating film INS1 are formed by a photolithography process, and the first conductive layers ML1 respectively connected to the first vias VA1 are formed on the first insulating film INS1 by a photolithography process. Then, the second insulating film INS2 is formed on the first conductive layers ML1, the second vias VA2 respectively connected to the first conductive layers ML1 while penetrating the second insulating film INS2 are formed by a photolithography process, and the second conductive layers ML2 respectively connected to the second vias VA2 are formed on the second insulating film INS2 by a photolithography process. Then, the third insulating film INS3 is formed on the second conductive layers ML2, the third vias VA3 respectively connected to the second conductive layers ML2 while penetrating the third insulating film INS3 are formed by a photolithography process, and the third conductive layers ML3 respectively connected to the third vias VA3 are formed on the third insulating film INS3 by a photolithography process. Then, the fourth insulating film INS4 is formed on the third conductive layers ML3, the fourth vias VA4 respectively connected to the third conductive layers ML3 while penetrating the fourth insulating film INS4 are formed by a photolithography process, and the fourth conductive layers ML4 respectively connected to the fourth vias VA4 are formed on the fourth insulating film INS4 by a photolithography process.

Then, the fifth insulating film INS5 is formed on the fourth conductive layers ML4, the fifth vias VA5 respectively connected to the fourth conductive layers ML4 while penetrating the fifth insulating film INS5 are formed by a photolithography process, and the fifth conductive layers ML5 respectively connected to the fifth vias VA5 are formed on the fifth insulating film INS5 by a photolithography process. Then, the sixth insulating film INS6 is formed on the fifth conductive layers ML5, the sixth vias VA6 respectively connected to the fifth conductive layers ML5 while penetrating the sixth insulating film INS6 are formed by a photolithography process, and the sixth conductive layers ML6 respectively connected to the sixth vias VA6 are formed on the sixth insulating film INS6 by a photolithography process. Then, the seventh insulating film INS7 is formed on the sixth conductive layers ML6, the seventh vias VA7 respectively connected to the sixth conductive layers ML6 while penetrating the seventh insulating film INS7 are formed by a photolithography process, and the seventh conductive layers ML7 respectively connected to the seventh vias VA7 are formed on the seventh insulating film INS7 by a photolithography process. Then, the eighth insulating film INS8 is formed on the seventh conductive layers ML7, the eighth vias VA8 respectively connected to the seventh conductive layers ML7 while penetrating the eighth insulating film INS8 are formed by a photolithography process, and the eighth conductive layers ML8 respectively connected to the eighth vias VA8 are formed on the eighth insulating film INS8 by a photolithography process. Then, the ninth insulating film INS9 is formed on the eighth conductive layers ML8, and the ninth vias VA9 respectively connected to the eighth conductive layers ML8 while penetrating the ninth insulating film INS9 are formed on the ninth insulating film INS9 by a photolithography process.

Then, the connection electrode layer ANCL connected to the ninth vias VA9 is formed on the ninth insulating film INS9, the reflective electrode layer RLL is formed on the connection electrode layer ANCL, and the first electrode layer ANDL is formed on the reflective electrode layer RLL. The connection electrode layer ANCL, the reflective electrode layer RLL, and the first electrode layer ANDL may be sequentially formed. The connection electrode layer ANCL, the reflective electrode layer RLL, and the first electrode layer ANDL may be formed on the entire one surface of the semiconductor substrate SSUB.

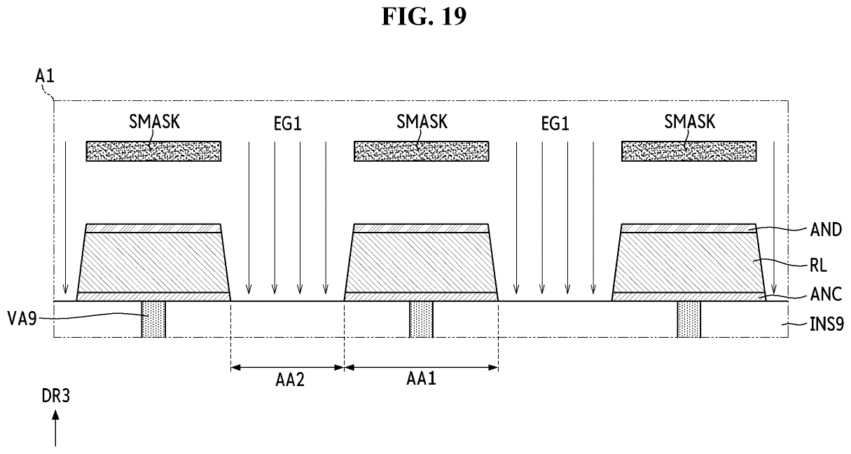

Secondly, as shown in FIGS. 7 and 19, the connection electrode layer ANCL, the reflective electrode layer RLL, and the first electrode layer ANDL are etched using a single mask SMASK to form the plurality of connection electrodes ANC, the plurality of reflective electrodes RL, and the plurality of first electrodes AND (S120 of FIG. 17).

Because the plurality of connection electrodes ANC, the plurality of reflective electrodes RL, and the plurality of first electrodes AND are patterned at once by a first etching material EG1 using the single mask SMASK, the side surface of the connection electrode ANC, the side surface of the reflective electrode RL, and the side surface of the first electrode AND may be aligned with each other. Therefore, the number of mask processes may be reduced compared to the case in which each of the plurality of first electrodes AND is connected to the exposed reflective electrode RL through a contact hole penetrating an insulating film, thereby reducing manufacturing cost for forming the plurality of connection electrodes ANC, the plurality of reflective electrodes RL, and the plurality of first electrodes AND, and increasing manufacturing efficiency.

In addition, the first sub-pad conductive layer SPML1, the second sub-pad conductive layer SPML2, and the third sub-pad conductive layer SPML3 of the first pad PD1 may be formed concurrently (e.g., simultaneously) with the plurality of connection electrodes ANC, the plurality of reflective electrodes RL, and the plurality of first electrodes AND using the single mask SMASK.

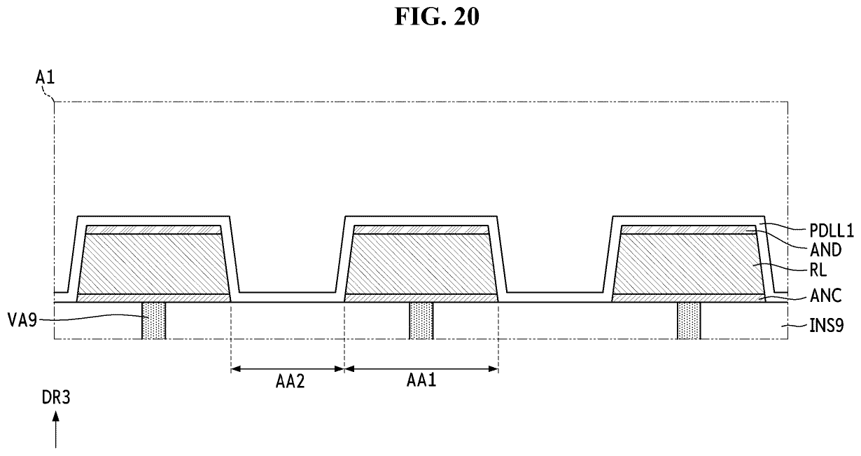

Thirdly, as shown in FIGS. 7 and 20, a first pixel defining layer PDLL1 is formed on the plurality of first electrodes AND (S130 of FIG. 17).

The first pixel defining layer PDLL1 may be formed on the side surface of each of the plurality of connection electrodes ANC, the side surface of each of the plurality of reflective electrodes RL, and the top and side surfaces of each of the plurality of first electrodes AND. The first pixel defining layer PDLL1 may be disposed on the ninth insulating film INS9 in the second area AA2 that does not overlap the plurality of connection electrodes ANC in the third direction DR3.

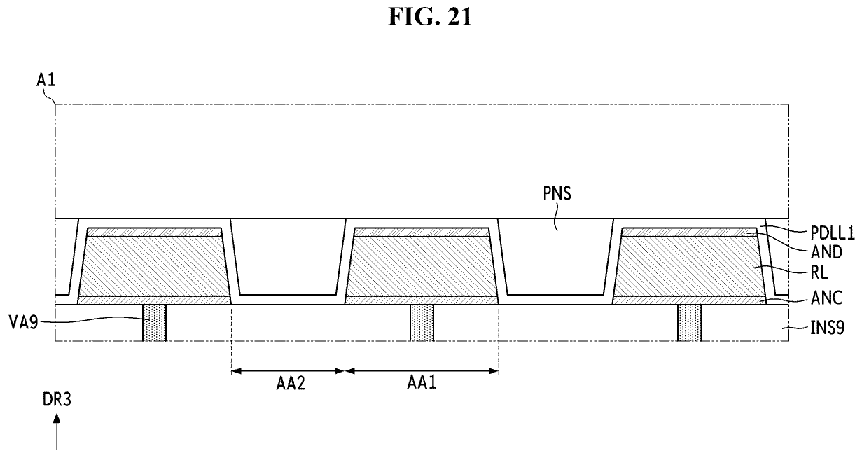

Fourthly, as shown in FIGS. 7 and 21, the planarization film PNS is formed on the first pixel defining layer PDLL1 (S140 of FIG. 17).

The planarization film PNS may be disposed on the first pixel defining layer PDLL1 disposed in the second area AA2 of the ninth insulating film INS9. After the planarization film PNS is formed to cover the first pixel defining layer PDLL1, the planarization film PNS may be polished through a chemical mechanical polishing process. As a result, the top surface of the first pixel defining layer PDLL1 and the top surface of the planarization film PNS may be continuously flat.

In addition, the planarization film PNS is formed as a silicon oxide (SiOx)-based inorganic film and the first pixel defining layer PDLL1 is formed as a silicon nitride (SiNₓ)-based inorganic film, so that the first pixel defining layer PDLL1 may act as a stopper in the above polishing process.

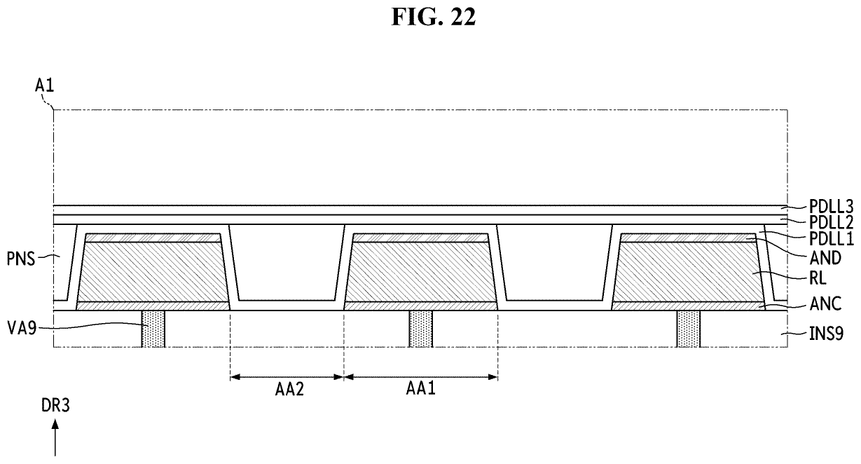

Fifthly, as shown in FIGS. 7 and 22, a second pixel defining layer PDLL2 and a third pixel defining layer PDLL3 are formed (S150 in FIG. 17).

The second pixel defining layer PDLL2 may be formed on the first pixel defining layer PDLL1 and the planarization film PNS. The third pixel defining layer PDLL3 may be formed on the second pixel defining layer PDLL2.

Sixthly, as shown in FIGS. 7 and 23-25 the first pixel defining film PDL1, the second pixel defining film PDL2, and the third pixel defining film PDL3 are formed (S160 of FIG. 17).

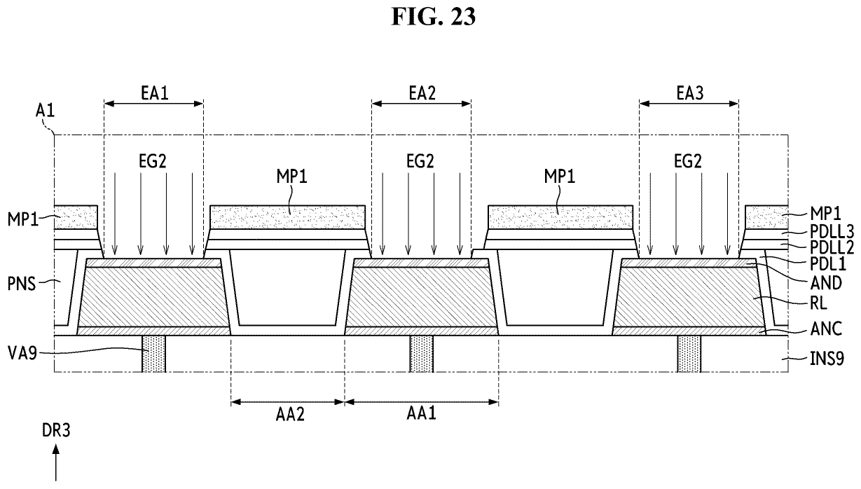

Initially, as shown in FIG. 23, a first mask pattern MP1 is formed on the third pixel defining layer PDLL3, and the first pixel defining layer PDLL1, the second pixel defining layer PDLL2, and the third pixel defining film PDLL3 that are not covered by the first mask pattern MP1 are etched using a second etching material EG2 to form the first pixel defining film PDL1. Then, the first mask pattern MP1 may be removed by an ashing process. The first mask pattern MP1 may be a photoresist pattern, but the present disclosure is not limited thereto.

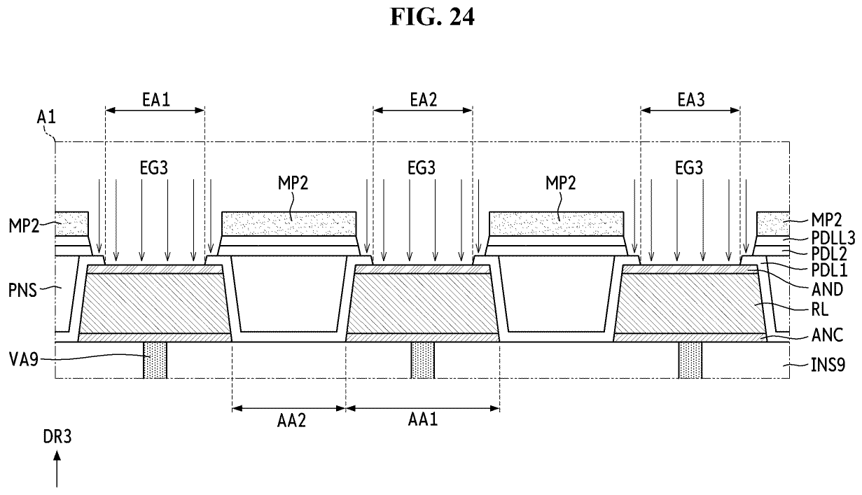

Then, as shown in FIG. 24, a second mask pattern MP2 is formed on the third pixel defining layer PDLL3, and the second pixel defining layer PDLL2 and the third pixel defining layer PDLL3 that are not covered by the second mask pattern MP2 are etched using a third etching material EG3 to form the second pixel defining film PDL2. Then, the second mask pattern MP2 may be removed by an ashing process.

The second mask pattern MP2 may be a photoresist pattern, but the present disclosure is not limited thereto.

Then, a third mask pattern MP3 is formed on the third pixel defining layer PDLL3, and the third pixel defining layer PDLL3 that is not covered by the third mask pattern MP3 is etched using a fourth etching material EG4 to form the third pixel defining film PDL3. Then, the third mask pattern MP3 may be removed by an ashing process. The third mask pattern MP3 may be a photoresist pattern, but the present disclosure is not limited thereto.

As such, when the first pixel defining film PDL1, the second pixel defining film PDL2, and the third pixel defining film PDL3 are formed in this order, during the process of etching the second pixel defining layer PDLL2 and the third pixel defining layer PDLL3 to form the second pixel defining film PDL2, the side surface of the first pixel defining film PDL1 exposed without being covered by the second pixel defining layer PDLL2 may be etched. As a result, the side surface of the first pixel defining film PDL1 may be formed to be inclined. In addition, during the process of etching the third pixel defining layer PDLL3 to form the third pixel defining film PDL3, the side surface of the second pixel defining film PDL2 exposed without being covered by the third pixel defining layer PDLL3 may be etched. As a result, the side surface of the second pixel defining film PDL2 may be formed to be inclined.

Seventhly, as shown in FIGS. 27 and 28, a fourth mask pattern MP4 is formed on the third sub-pad conductive layer SPML3 (S170 of FIG. 17).

The fourth mask pattern MP4 may be formed on the second portion SMP2 of the third sub-pad conductive layer SPML3 that is exposed without being covered by the first pixel defining film PDL1. The fourth mask pattern MP4 may not be formed on the second portion ANDP2 of each of the plurality of first electrodes AND that is exposed without being covered by the first pixel defining film PDL1. The fourth mask pattern MP4 may be a photoresist pattern, but the present disclosure is not limited thereto.

Eighthly, as shown in FIGS. 27 and 28, the second portion ANDP2 of each of the plurality of first electrodes AND exposed without being covered by the first pixel defining film PDL1 is etched using a fifth etching material EG5 (S180 of FIG. 17).

The thickness TT2 of the second portion ANDP2 of each of the first electrodes AND may be less than the thickness TT1 of the first portion ANDP1 of each of the first electrodes AND.

Because the fourth mask pattern MP4 is formed on the second portion SMP2 of the third sub-pad conductive layer SPML3, the second portion SMP2 of the third sub-pad conductive layer SPML3 may not be etched. The thickness TT2_1 of the second portion SMP2 of the third sub-pad conductive layer SPML3 may be substantially the same as the thickness TT1_1 of the first portion SMP1 of the third sub-pad conductive layer SPML3.

The fourth mask pattern MP4 may be removed by an ashing process.

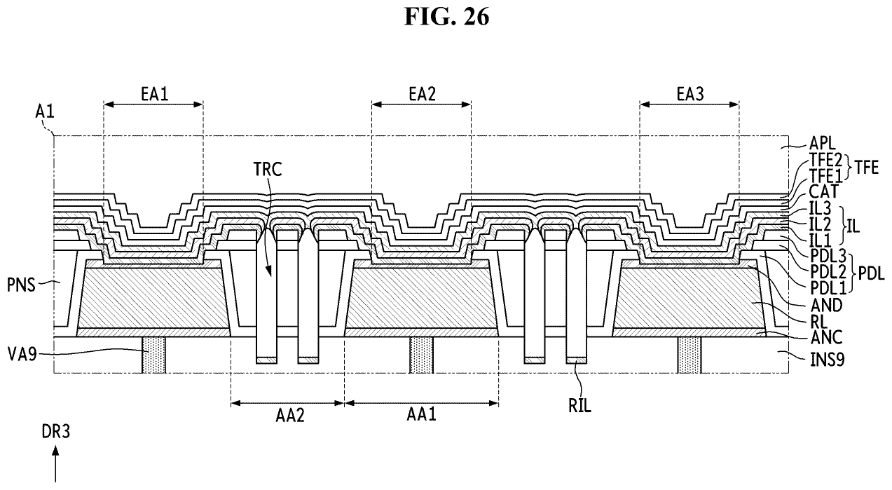

Ninthly, as shown in FIG. 26, the plurality of trenches TRC, the light-emitting stack IL, the second electrode CAT, the encapsulation layer TFE, and the optical layer OPL are formed, and the cover layer CVL and the polarizing plate POL are attached (S190 of FIG. 17).

Each of the plurality of trenches TRC may be a hole formed by penetrating the first pixel defining film PDL1, the second pixel defining film PDL2, the third pixel defining film PDL3, and the planarization film PNS, and partially recessing the ninth insulating film INS9. The plurality of trenches TRC may be formed by a lithography process using argon fluoride (ArF) as a photoresist. Alternatively, the plurality of trenches TRC may be formed by a lithography process using krypton fluoride (ArF) as a photoresist.

Then, the first stack layer IL1, the second stack layer IL2, and the third stack layer IL3 of the light-emitting stack IL may be formed on the plurality of first electrodes AND, the first pixel defining film PDL1, the second pixel defining film PDL2 and the third pixel defining film PDL3. In addition, the first stack layer IL1 and the second stack layer IL2 may be cut off in each of the trenches TRC. Therefore, the first charge generation layer disposed between the first stack layer IL1 and the second stack layer IL2 and the second charge generation layer disposed between the second stack layer IL2 and the third stack layer IL3 may also be cut off. Accordingly, the current flowing in each of the sub-pixels SP1, SP2, and SP3 may be prevented from flowing to the neighboring sub-pixel through the first charge generation layer and the second charge generation layer.

Then, the second electrode CAT is formed on the third stack layer IL3, and the first encapsulation inorganic film TFE1 and the second encapsulation inorganic film TFE2 of the encapsulation layer TFE are sequentially formed on the second electrode CAT. The first encapsulation inorganic film TFE1 may be formed by a chemical vapor deposition (CVD) process, and the second encapsulation inorganic film TFE2 may be formed by an atomic layer deposition (ALD) process.

Then, the organic film APL is formed on the encapsulation layer TFE, and

the first color filters CF1 overlapping the first emission areas EA1, the second color filters CF2 overlapping the second emission areas EA2, and the third color filters CF3 overlapping the third emission areas EA3 are formed on the organic film APL.

Thereafter, the plurality of lenses LNS are formed on the first color filters CF1, the second color filters CF2, and the third color filters CF3, respectively. That is, the plurality of lenses LNS may be formed to correspond one-to-one to the color filters CF1, CF2, and CF3.

Then, the filling layer FIL is formed on the plurality of lenses LNS, and the cover layer CVL is provided on the filling layer FIL.

The cover layer CVL may be a glass substrate and/or a polymer resin.

When the cover layer CVL is a glass substrate, it may serve as an encapsulation substrate, and the filling layer FIL may serve to adhere the cover layer CVL. When the cover layer CVL is a polymer resin, it may be directly applied onto the filling layer FIL. Then, the polarizing plate POL is attached on the cover layer CVL.

Alternatively, as shown in FIGS. 15 and 16, the first light-emitting layer IL1_1 may be formed on the first electrode AND of each of the first emission areas EA1, the second light-emitting layer IL2_1 may be formed on the first electrode AND of each of the second emission areas EA2, and the third light-emitting layer IL3_1 may be formed on the first electrode AND of each of the third emission areas EA3. In this case, the second electrode CAT may be formed on the first light-emitting layer IL1_1, the second light-emitting layer IL2_1, and the third light-emitting layer IL3_1. In addition, as shown in FIG. 15, the first color filters CF1, the second color filters CF2, the third color filters CF3, the plurality of lenses LNS, and the filling layer FIL may be omitted.

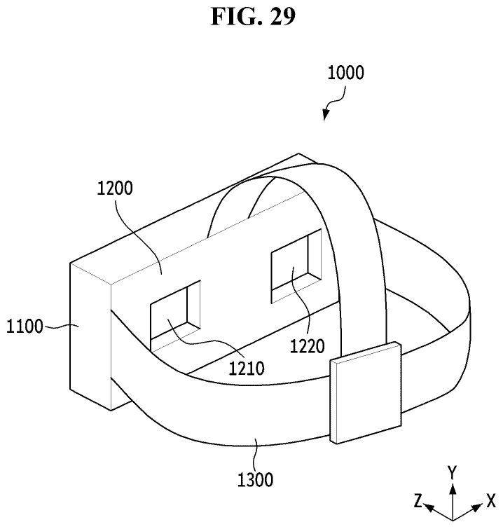

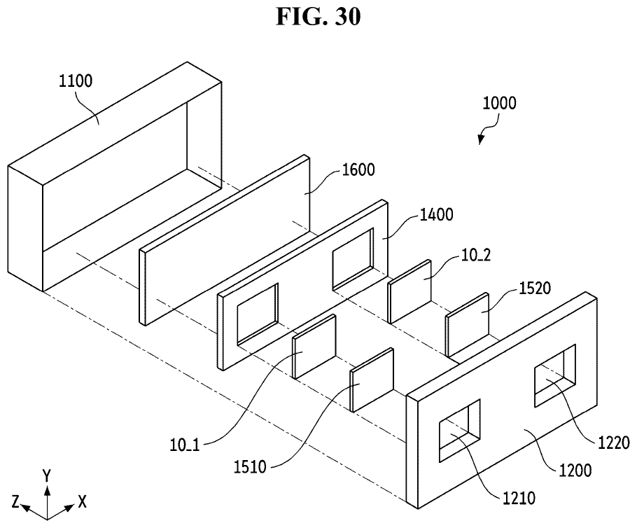

FIG. 29 is a perspective view illustrating a head mounted display according to one or more embodiments. FIG. 30 is an exploded perspective view illustrating an example of the head mounted display of FIG. 29.

Referring to FIGS. 29 and 30, a head mounted display 1000 according to one or more embodiments includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is substantially the same as the display device 10 described in conjunction with FIGS. 1 and 2, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 29 and 30 illustrate that the first eyepiece 1210 and the second eyepiece 1220 are disposed separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

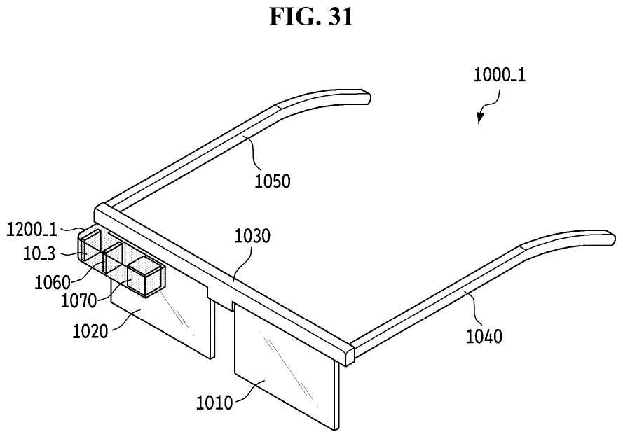

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with, as shown in FIG. 31, an eyeglass frame instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

FIG. 31 is a perspective view illustrating a head mounted display according to one or more embodiments.

Referring to FIG. 31, a head mounted display 1000_1 according to one or more embodiments may be an eyeglasses-type display device in which a display device housing 1200_1 is implemented in a lightweight and compact manner. The head mounted display 1000_1 according to one or more embodiments may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 31 illustrates that the display device housing 1200_1 is disposed at the right end of the support frame 1030, but the present disclosure is not limited thereto. For example, the display device housing 1200_1 may be disposed at the left end of the support frame 1030, and in this case, the image of the display device 10_3 may be provided to the user's left eye. Alternatively, the display device housing 1200_1 may be disposed at both the left and right ends of the support frame 1030, and in this case, the user may view the image displayed on the display device 10_3 through both the left and right eyes.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
an insulating film on the substrate;
a connection electrode on the insulating film;
a reflective electrode on the connection electrode;
a first electrode on the reflective electrode;
a first pixel defining film on a first portion of the first electrode and exposing a second portion of the first electrode;
at least one light-emitting layer on a second area of a top surface of the first electrode; and
a second electrode on the at least one light-emitting layer,
wherein a thickness of the second portion of the first electrode is less than a thickness of the first portion of the first electrode.

2. The display device of claim 1, wherein the first pixel defining film is on a side surface of the first electrode, a side surface of the reflective electrode, and a side surface of the connection electrode.

3. The display device of claim 1, wherein the insulating film comprises:
a first area overlapping the connection electrode in a thickness direction of the substrate; and
a second area around the first area, and
wherein the first pixel defining film is on the second area of the insulating film.

4. The display device of claim 3, further comprising a planarization film on the first pixel defining film on the second area of the insulating film,
wherein the first pixel defining film comprises an inorganic material different from the planarization film.

5. The display device of claim 4, further comprising a second pixel defining film on the planarization film and the first pixel defining film.

6. The display device of claim 5, further comprising a trench penetrating the first pixel defining film, the planarization film, and the second pixel defining film.

7. The display device of claim 1, further comprising:
a first pad conductive layer on the insulating film and comprising a same material as the connection electrode;
a second pad conductive layer on the first pad conductive layer and comprising a same material as the reflective electrode; and
a third pad conductive layer on the second pad conductive layer and comprising a same material as the first electrode.

8. The display device of claim 7, wherein the first pixel defining film is on a first portion of the third pad conductive layer, and exposes a second portion of the third pad conductive layer.

9. The display device of claim 7, wherein a thickness of the second portion of the first electrode is less than a thickness of the third pad conductive layer.

10. The display device of claim 7, wherein a thickness of the first portion of the first electrode is a same as a thickness of the third pad conductive layer.

11. A display device comprising:
a substrate;
an insulating film on the substrate;
a connection electrode on the insulating film;
a reflective electrode on the connection electrode;
a first electrode on the reflective electrode;
a first pad conductive layer on the insulating film and comprising a same material as the connection electrode;
a second pad conductive layer on the first pad conductive layer and comprising a same material as the reflective electrode;
a third pad conductive layer on the second pad conductive layer and comprising a same material as the first electrode,
a first pixel defining film on a first portion of the first electrode and exposing a second portion of the first electrode;
at least one light-emitting layer on a second area of a top surface of the first electrode; and
a second electrode on the at least one light-emitting layer,
wherein a thickness of the second portion of the first electrode is less than a thickness of the third pad conductive layer.

12. The display device of claim 11, wherein a thickness of the second portion of the first electrode is less than a thickness of the first portion of the first electrode.

13. The display device of claim 11, wherein a thickness of the first portion of the first electrode is a same as a thickness of the third pad conductive layer.

14. The display device of claim 11, wherein the first pixel defining film is on a first portion of the third pad conductive layer, and exposes a second portion of the third pad conductive layer.

15. A method for manufacturing a display device, comprising:
forming an insulating film on a substrate, forming a connection electrode layer on the insulating film, forming a reflective electrode layer on the connection electrode layer, and forming a first electrode layer on the reflective electrode layer;
etching the connection electrode layer, the reflective electrode layer, and the first electrode layer using a single mask to form a plurality of connection electrodes, a plurality of reflective electrodes, and a plurality of first electrodes;
forming a pixel defining film on a first portion of each of the plurality of first electrodes and exposing a second portion thereof; and
etching the second portion of each of the plurality of first electrodes such that a thickness of the second portion of each of the plurality of first electrodes is less than a thickness of the first portion of each of the plurality of first electrodes.

16. The method of claim 15, wherein the etching of the connection electrode layer, the reflective electrode layer, and the first electrode layer using the single mask to form the plurality of connection electrodes, the plurality of reflective electrodes, and the plurality of first electrodes comprises:
etching the connection electrode layer, the reflective electrode layer, and the first electrode layer using the single mask to form a pad conductive layer concurrently with the plurality of connection electrodes, the plurality of reflective electrodes, and the plurality of first electrodes.

17. The method of claim 16, wherein the pad conductive layer comprises:
a first pad conductive layer comprising a same material as the plurality of connection electrodes;
a second pad conductive layer comprising a same material as the plurality of reflective electrodes; and
a third pad conductive layer comprising a same material as the plurality of first electrodes.

18. The method of claim 17, wherein the forming of the pixel defining film on the first portion of each of the plurality of first electrodes and exposing the second portion thereof comprises:
forming the pixel defining film on a first portion of the third pad conductive layer and exposing a second portion thereof.

19. The method of claim 18, further comprising, before etching the second portion of each of the plurality of first electrodes such that the thickness of the second portion of each of the plurality of first electrodes is less than the thickness of the first portion of each of the plurality of first electrodes, forming a mask pattern covering the second portion of the third pad conductive layer.

20. A head mounted display comprising:
at least one display device;
a housing configured to accommodate the at least one display device; and
an optical member configured to magnify a display image of the at least one display device or change an optical path,
wherein the at least one display device comprises:
a substrate;
an insulating film on the substrate;
a connection electrode on the insulating film;
a reflective electrode on the connection electrode;
a first electrode on the reflective electrode;
a first pixel defining film on a first portion of the first electrode and exposing a second portion of the first electrode;
at least one light-emitting layer on a second area of a top surface of the first electrode; and
a second electrode on the at least one light-emitting layer,
wherein a thickness of the second portion of the first electrode is less than a thickness of the first portion of the first electrode.

21. An electronic device comprising:
a display device; and
a processor configured to provide input image data to the display device, the display device comprising:
a substrate;
an insulating film on the substrate;
a connection electrode on the insulating film;
a reflective electrode on the connection electrode;
a first electrode on the reflective electrode;
a first pixel defining film on a first portion of the first electrode and exposing a second portion of the first electrode;
at least one light-emitting layer on a second area of a top surface of the first electrode;
a second electrode on the at least one light-emitting layer; and
a first pad conductive layer on the insulating film and comprising a same material as the connection electrode,
wherein a thickness of the second portion of the first electrode is less than a thickness of the first portion of the first electrode.

22. The electronic device of claim 21, wherein the electronic device comprises a mobile phone, a smartphone, a tablet personal computer, a mobile communication terminal, an electronic organizer, an electronic book, a portable multimedia player (PMP), a navigation system, an ultra mobile PC (UMPC), a television, a laptop, a monitor, a billboard, or an Internet-of-Things (IoT) terminal.
